(19) United States
(12) Patent Application Publication
(10) Pub. No.: US 2025/0192042 A1
(43) Pub. Date: Jun. 12, 2025

(54) INTEGRATED CIRCUIT DEVICE INCLUDING A METAL WIRING LAYER

(71) Applicant: SAMSUNG ELECTRONICS CO., LTD., SUWON-SI (KR)

(72) Inventors: Wonsuk LEE, Suwon-si (KR); Jisoo OH, Suwon-si (KR)

(21) Appl. No.: 18/825,224

(22) Filed: Sep. 5, 2024

(30) Foreign Application Priority Data
Dec. 8, 2023 (KR) 10-2023-0178052

(51) Int. Cl. H01L 23/528; H01L 23/532

(52) U.S. Cl. CPC H01L 23/5283; H01L 23/528; H01L 23/53295

(57) ABSTRACT

An integrated circuit device includes: a lower insulating film arranged on a substrate; a lower metal wiring layer passing through the lower insulating film; an upper insulating film arranged on the lower insulating film and the lower metal wiring layer; an upper metal wiring layer arranged on the upper insulating film; and a conductive contact plug passing through the upper insulating film in a vertical direction and disposed between the lower metal wiring layer and the upper metal wiring layer, wherein a first center of an uppermost portion farthest from the substrate, of the conductive contact plug, is shifted in a first direction, which is parallel to a main surface of the substrate, from a second center of a lowermost portion closest to the substrate, of the conductive contact plug.

### CROSS-REFERENCE TO RELATED APPLICATION

This application claims priority under 35 U.S.C. § 119 to Korean Patent Application No. 10-2023-0178052, filed on Dec. 8, 2023, in the Korean Intellectual Property Office, the disclosure of which is incorporated by reference herein in its entirety.

### TECHNICAL FIELD

Embodiments of the present inventive concept relate to an integrated circuit device, and more particularly, to an integrated circuit device including a metal wiring layer.

### DISCUSSION OF THE RELATED ART

Due to the advancements in electronics technology, integrated circuit devices have been rapidly reduced in size, and the line widths and pitches of metal wiring layers in integrated circuit devices also have been fine-sized. Therefore, it is desirable to increase the electrical reliability of metal wiring layers by reducing the possibility of short-circuits between adjacent metal wiring structures.

### SUMMARY

According to embodiments of the present inventive concept, an integrated circuit device includes: a lower insulating film arranged on a substrate; a lower metal wiring layer passing through the lower insulating film; an upper insulating film arranged on the lower insulating film and the lower metal wiring layer; an upper metal wiring layer arranged on the upper insulating film; and a conductive contact plug passing through the upper insulating film in a vertical direction and disposed between the lower metal wiring layer and the upper metal wiring layer, wherein a first center of an uppermost portion farthest from the substrate, of the conductive contact plug, is shifted in a first direction, which is parallel to a main surface of the substrate, from a second center of a lowermost portion closest to the substrate, of the conductive contact plug.

According to embodiments of the present inventive concept, an integrated circuit device includes: a lower insulating film arranged on a substrate; a plurality of lower metal wiring layers spaced apart from each other in a first direction and extending lengthwise in a second direction that intersects with the first direction, wherein each of the plurality of lower metal wiring layers are disposed in the lower insulating film; an upper insulating film arranged on the lower insulating film and the plurality of lower metal wiring layers; a first upper metal wiring layer arranged on the upper insulating film to overlap a first lower metal wiring layer of the plurality of lower metal wiring layers and a second lower metal wiring layer of the plurality of lower metal wiring layers, and extending lengthwise in the first direction; a first conductive contact plug disposed in the upper insulating film and contacting each of the first lower metal wiring layer and the first upper metal wiring layer; and a second conductive contact plug disposed in the upper insulating film and contacting each of the second lower metal wiring layer and the first upper metal wiring layer, wherein, in each of the first conductive contact plug and the second conductive contact plug, a first center of an uppermost portion farthest from the substrate is shifted in the first direction, which is parallel to a main surface of the substrate, from a second center of a lowermost portion closest to the substrate.

According to embodiments of the present inventive concept, an integrated circuit device includes: a lower structure arranged on a substrate; a lower insulating film arranged on the lower structure; a plurality of lower metal wiring layers spaced apart from each other in a first direction and extending lengthwise in a second direction that intersects with the first direction, wherein each of the plurality of lower metal wiring layers pass through the lower insulating film; an etch stop film arranged on the lower insulating film and the plurality of lower metal wiring layers and having a multilayered structure that includes at least one aluminum (Al)-containing film; an upper insulating film covering an upper surface of the etch stop film; a first upper metal wiring layer arranged on the upper insulating film to overlap a first lower metal wiring layer of the plurality of lower metal wiring layers and a second lower metal wiring layer of the plurality of lower metal wiring layers, and extending lengthwise in the first direction; a first conductive contact plug passing through the upper insulating film and the etch stop film and disposed between the first lower metal wiring layer and the first upper metal wiring layer; and a second conductive contact plug passing through the upper insulating film and the etch stop film and disposed between the second lower metal wiring layer and the first upper metal wiring layer, wherein, in each of the first conductive contact plug and the second conductive contact plug, a first center of an uppermost portion farthest from the substrate is shifted in the first direction or the second direction from a second center of a lowermost portion closest to the substrate, and a central-axis extension direction of each of the first conductive contact plug and the second conductive contact plug varies as the substrate is approached from the upper metal wiring layer.

### BRIEF DESCRIPTION OF THE DRAWINGS

The above and other aspects of the present inventive concept will become more apparent by describing in detail embodiments thereof, with reference to the accompanying drawings, in which:

FIG. 1 is a planar layout diagram illustrating an integrated circuit device according to embodiments of the present inventive concept;

FIG. 2 is a cross-sectional view of the integrated circuit device of FIG. 1, taken along the line X1-X1′ of FIG. 1;

FIG. 3 is a schematic cross-sectional view of an integrated circuit device according to embodiments of the present inventive concept;

FIG. 4 is a schematic cross-sectional view of an integrated circuit device according to embodiments of the present inventive concept;

FIG. 5 is a schematic cross-sectional view of an integrated circuit device according to embodiments of the present inventive concept;

FIG. 6 is a planar layout diagram illustrating an integrated circuit device according to embodiments of the present inventive concept;

FIG. 7 is a cross-sectional view of the integrated circuit device of FIG. 6, taken along the line X1-X1′ of FIG. 6;

FIG. 8 is a cross-sectional view of the integrated circuit device of FIG. 6, taken along the line Y1-Y1′ of FIG. 6;

FIGS. 9 and 10 are cross-sectional views illustrating an integrated circuit device according to embodiments of the present inventive concept;

FIGS. 11, 12A, 13A, 14, 15, and 16 are cross-sectional views respectively illustrating a sequence of processes of example methods of fabricating an integrated circuit device, according to embodiments of the present inventive concept;

FIG. 12B is a plan view illustrating the process of FIG. 12A.

FIG. 13B is a plan view illustrating the process of FIG. 13A;

FIG. 17A is a timing pulse diagram illustrating an example method of fabricating an integrated circuit device, according to embodiments of the present inventive concept;

FIG. 17B is a cross-sectional view illustrating, as an example, a method of fabricating an integrated circuit device, according to embodiments of the present inventive concept; and

FIGS. 18A, 18B, 18C, and 18D are cross-sectional views respectively illustrating, as examples, a sequence of processes of methods of fabricating an integrated circuit device, according to embodiments of the present inventive concept.

### DETAILED DESCRIPTION OF THE EMBODIMENTS

Hereinafter, embodiments of the present inventive concept will be described in detail with reference to the accompanying drawings. Like components are denoted by like reference numerals throughout the specification and drawings, and repeated descriptions thereof are omitted or briefly discussed.

Although the terms such as “first”, “second”, “third” and the like may be used herein to describe various components, these terms are used only to distinguish one component from another component, and these components should not be limited by these terms. For example, a first component, a second component, and a third component may each be referred to as just a “component” without departing from the scope of the inventive concept. In addition, unless otherwise stated, a first component could be termed a second component or a second component could also be termed a first component.

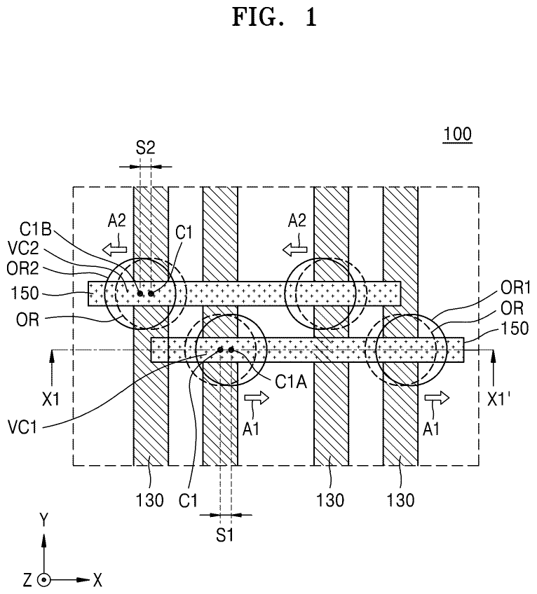

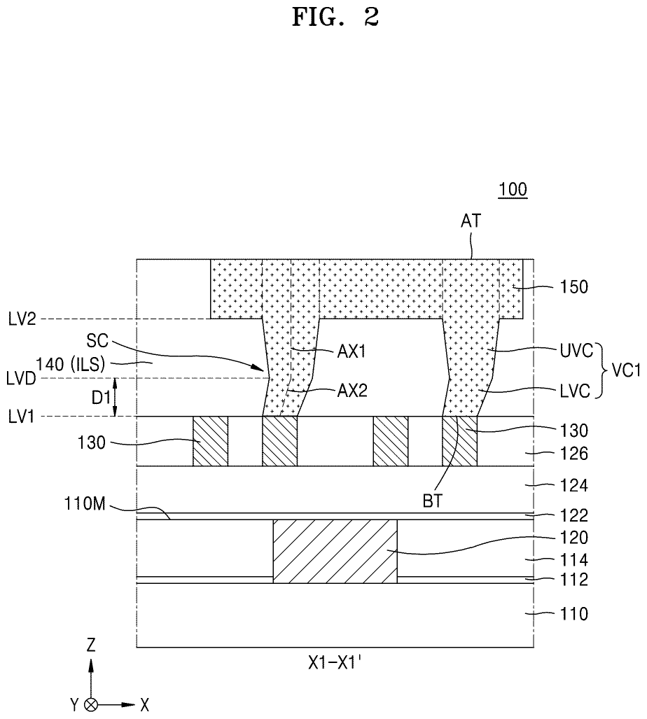

FIG. 1 is a planar layout diagram illustrating an integrated circuit device 100 according to embodiments of the present inventive concept. FIG. 2 is a cross-sectional view of the integrated circuit device 100, taken along the line X1-X1 of FIG. 1.

Referring to FIGS. 1 and 2, the integrated circuit device 100 may include a lower structure arranged on a substrate 110. The lower structure may include a first etch stop film 112, a first interlayer dielectric 114, a second lower etch stop film 122, and a second interlayer dielectric 124, which are arranged in the stated order in the vertical direction (the Z direction) on the substrate 110 and may also include a conductive structure 120 passing through the first interlayer dielectric 114 and the second lower etch stop film 122 in the vertical direction (the Z direction).

The substrate 110 may include a semiconductor, such as Si or Ge, or a compound semiconductor, such as SiGe, SiC, GaAs, InAs, or InP. The substrate 110 may include a conductive region. The conductive region may include an impurity-doped well, an impurity-doped structure, or a conductive layer. The substrate 110 may include circuit elements, such as a gate structure, an impurity region, a contact plug, and the like.

Each of the first interlayer dielectric 114 and the second interlayer dielectric 124 may include a silicon oxide film. For example, each of the first interlayer dielectric 114 and the second interlayer dielectric 124 may include a silicon oxide-based material, such as plasma-enhanced oxide (PEOX), tetraethyl orthosilicate (TEOS), boro-TEOS (BTEOS), phosphorous TEOS (PTEOS), boro-phospho-TEOS (BPTEOS), boro-silicate glass (BSG), phospho-silicate glass (PSG), boro-phospho-silicate glass (BPSG), or the like. In embodiments of the present inventive concept, each of the first interlayer dielectric 114 and the second interlayer dielectric 124 may include a low-K film having a low dielectric constant (that is, K) of about 2.2 to about 3.0, for example, an SiOC film or an SiCOH film.

Each of the first etch stop film 112 and the second lower etch stop film 122 may include a material having different etch selectivity from a constituent material of each of the first interlayer dielectric 114 and the second interlayer dielectric 124. For example, each of the first etch stop film 112 and the second lower etch stop film 122 may include a silicon nitride film, a carbon-doped silicon nitride film, or a carbon-doped silicon oxynitride film. In embodiments of the present inventive concept, each of the first etch stop film 112 and the second lower etch stop film 122 may include an insulating metal oxide film, an insulating metal nitride film, or a combination thereof. For example, each of the first etch stop film 112 and the second lower etch stop film 122 may include an aluminum oxide (AlO) film, an aluminum nitride (AlN) film, or a combination thereof.

The conductive structure 120 may include a wiring layer, which includes a metal film and a conductive barrier film at least partially surrounding the metal film. In the conductive structure 120, the metal film may include, for example, Cu, W, Mo, Ru, Co, Al, or a combination thereof, and the conductive barrier film may include, for example, a TiN film, a TaN film, a Co film, or a combination thereof, but the present inventive concept is not limited thereto. In embodiments of the present inventive concept, the conductive structure 120 may be configured to be electrically connected with the conductive region formed in the substrate 110. In embodiments of the present inventive concept, the conductive structure 120 may be configured to be connected to a source/drain region or a gate electrode of a transistor formed in the substrate 110.

A lower insulating film 126 may be arranged on the second interlayer dielectric 124, and a plurality of lower metal wiring layers 130 may pass through the lower insulating film 126 in the vertical direction (the Z direction). The plurality of lower metal wiring layers 130 may be arranged spaced apart from each other in a first horizontal direction (an X direction) and may extend lengthwise in a second horizontal direction (a Y direction) intersecting with the first horizontal direction (the X direction). In embodiments of the present inventive concept, the first horizontal direction (the X direction) and the second horizontal direction (the Y direction) may be orthogonal to each other. The plurality of lower metal wiring layers 130 may extend in the second horizontal direction (the Y direction) and may be parallel to each other.

An upper insulating film 140 may be arranged on the lower insulating film 126 and the plurality of lower metal wiring layers 130. Herein, the upper insulating film 140 may be referred to as an upper insulating structure ILS. A plurality of upper metal wiring layers 150 may be arranged on the upper insulating film 140. Each of the plurality of upper metal wiring layers 150 may be arranged to overlap, in the vertical direction, at least one lower metal wiring layer 130 selected from the plurality of lower metal wiring layers 130. Each of the plurality of upper metal wiring layers 150 may extend lengthwise in the first horizontal direction (the X direction).

Constituent materials of the lower insulating film 126 and the upper insulating film 140 may be respectively and substantially the same as the constituent materials of the first interlayer dielectric 114 and the second interlayer dielectric 124, which are described above. The plurality of lower metal wiring layers 130 and the plurality of upper metal wiring layers 150 may each include a metal film, a conductive metal nitride film, or a combination thereof. In embodiments of the present inventive concept, at least one of the plurality of lower metal wiring layers 130 and the plurality of upper metal wiring layers 150 may include a metal plug and a conductive barrier film at least partially surrounding the sidewall and the lower surface of the metal plug. The metal plug may include, for example, Cu, W, Mo, Ru, Co, Al, or a combination thereof. For example, the metal plug may include Cu. The conductive barrier film may include, for example, a TiN film, a TaN film, a Co film, or a combination thereof. For example, when the metal plug includes Cu, the conductive barrier film may have a multilayered structure including a TaN film and a Co film, but the present inventive concept is not limited thereto.

A plurality of conductive contact plugs VC1 and VC2 may pass through the upper insulating film 140 in the vertical direction (the Z direction). The plurality of conductive contact plugs VC1 and VC2 may include a conductive contact plug VC1, which is in contact with one (e.g., a first) upper metal wiring layer 150 selected from the plurality of upper metal wiring layers 150, and a conductive contact plug VC2, which is in contact with another (e.g., a second) upper metal wiring layer 150 selected from the plurality of upper metal wiring layers 150. Each of the plurality of conductive contact plugs VC1 and VC2 may be in contact with one lower metal wiring layer 130 selected from the plurality of lower metal wiring layers 130 and with one upper metal wiring layer 150 selected from the plurality of upper metal wiring layers 150.

As shown in FIG. 2, at least one conductive contact plug VC1 selected from a plurality of conductive contact plugs VC1 may be integrally connected with an upper metal wiring layer 150. In addition, at least one conductive contact plug VC2 selected from a plurality of conductive contact plugs VC2 may be integrally connected with an upper metal wiring layer 150.

As each of the plurality of conductive contact plugs VC1 and VC2 gets closer to the substrate 110 from the upper metal wiring layer 150 corresponding to each thereof, a central-axis extension direction of each of the plurality of conductive contact plugs VC1 and VC2 may vary. For example, as shown in FIG. 2, in each of the plurality of conductive contact plugs VC1, a first central axis AX1 of an upper contact portion UVC adjacent to the upper metal wiring layer 150 may extend in the vertical direction (the Z direction), and in each of the plurality of conductive contact plugs VC1, a second central axis AX2 of a lower contact portion LVC adjacent to the lower metal wiring layer 130 may extend in a direction that is tilted or slanted in a first direction (for example, the right direction in FIGS. 1 and 2) with respect to the first central axis AX1. For example, in each of the plurality of conductive contact plugs VC1, the second central axis AX2 of the lower contact portion LVC adjacent to the lower metal wiring layer 130 may extend in a direction that is tilted at an angle that is greater than about 0 degrees and less than about 30 degrees in the first direction (for example, the right direction in FIGS. 1 and 2) with respect to the first central axis AX1. For example, each of the plurality of conductive contact plugs VC1 may be bent. In addition, similar to the plurality of conductive contact plugs VC1, in the plurality of conductive contact plugs VC2, a first central axis of an upper contact portion UVC, which is adjacent to the upper metal wiring layer 150 corresponding to each of the plurality of conductive contact plugs VC2, and a second central axis of a lower contact portion LVC, which is adjacent to the lower metal wiring layer 130, may respectively extend in different directions from each other. However, in each of the plurality of conductive contact plugs VC2, the first central axis of the upper contact portion UVC adjacent to the upper metal wiring layer 150 may extend in the vertical direction (the Z direction), and the second central axis of the lower contact portion LVC adjacent to the lower metal wiring layer 130 may extend in a direction that is tilted in the direction (for example, the left direction in FIGS. 1 and 2) opposite to the first direction with respect to the first central axis of the upper contact portion UVC. For example, in each of the plurality of conductive contact plugs VC2, the second central axis of the lower contact portion LVC adjacent to the lower metal wiring layer 130 may extend in a direction that is tilted at an angle greater than about 0 degrees and less than about 30 degrees in the direction (for example, the left direction in FIGS. 1 and 2) opposite to the first direction with respect to the first central axis of the upper contact portion UVC.

As shown in FIG. 2, the sidewall of each of the plurality of conductive contact plugs VC1 and VC2 may include a slope change portion SC, which has a change in the slope of the sidewall, between the upper contact portion UVC and the lower contact portion LVC. A vertical level LVD of the slope change portion SC of each of the plurality of conductive contact plugs VC1 and VC2 may be higher than a first vertical level LV1 of the upper surface of each of the plurality of lower metal wiring layers 130 and lower than a second vertical level LV2 of the lower surface of each of the plurality of upper metal wiring layers 150. A vertical distance D1 from the first vertical level LV1 of the upper surface of each lower metal wiring layer 130 to the vertical level LVD of the slope change portion SC of each of the plurality of conductive contact plugs VC1 and VC2 may be greater than 0 and less than the difference between the second vertical level LV2 of the lower surface of each upper metal wiring layer 150 and the first vertical level LV1 of the upper surface of each lower metal wiring layer 130.

As shown in FIGS. 1 and 2, in each of the plurality of conductive contact plugs VC1 and VC2, a center C1A or C1B of an uppermost portion AT, which is farthest from the substrate 110, may be shifted in a horizontal direction (for example, the X direction, the −X direction, the Y direction, or the −Y direction), which is parallel to a main surface 110M of the substrate 110, from a center C1 of a lowermost portion BT closest to the substrate 110. In each of the plurality of conductive contact plugs VC1 and VC2, the center C1 of the lowermost portion BT may correspond to the center of an interface region between the lower metal wiring layer 130 and the upper metal wiring layer 150. Herein, the center C1 of the lowermost portion BT of each of the plurality of conductive contact plugs VC1 and VC2 may be referred to as a reference center.

As shown in FIG. 1, in the viewpoint of a plane (the X-Y plane in FIG. 1), the center C1A or C1B of the uppermost portion AT (see FIG. 2) of each of the plurality of conductive contact plugs VC1 and VC2 may be arranged at a position shifted in the horizontal direction (for example, the X direction, the −X direction, the Y direction, or the −Y direction), which is parallel to a main surface 110M of the substrate 110, from the center C1 (that is, the reference center) of the lowermost portion BT of each of the plurality of conductive contact plugs VC1 and VC2. Similarly, in the viewpoint of a plane (the X-Y plane in FIG. 1), an imaginary upper-surface overlay circle OR1 or OR2 having, as the center thereof, the center C1A or C1B of the uppermost portion AT (see FIG. 2) of each of the plurality of conductive contact plugs VC1 and VC2 may be arranged at a position shifted in the horizontal direction (for example, the X direction, the −X direction, the Y direction, or the −Y direction) from an imaginary reference overlay circle OR having, as the center thereof, the center C1 (that is, the reference center) of the lowermost portion BT of each of the plurality of conductive contact plugs VC1 and VC2.

FIG. 1 illustrates that, in some conductive contact plugs VC1 selected from the plurality of conductive contact plugs VC1 and VC2, the center C1A of the uppermost portion AT farthest from the substrate 110 is shifted by a distance S1 greater than 0 in the first horizontal direction (the X direction) as indicated by the arrow A1 from the center C1 (that is, the reference center) of the lowermost portion BT, in the viewpoint of a plane (the X-Y plane in FIG. 1). In addition, FIG. 1 also illustrates that, in some other conductive contact plugs VC2 selected from the plurality of conductive contact plugs VC1 and VC2, the center C1B of the uppermost portion AT farthest from the substrate 110 is shifted by a distance S2 greater than 0 in the direction (the −X direction) opposite to the first horizontal direction (the X direction) as indicated by the arrow A2 from the center C1 (that is, the reference center) of the lowermost portion BT, in the viewpoint of a plane (the X-Y plane in FIG. 1).

In embodiments of the present inventive concept, the plurality of conductive contact plugs VC1 connected to one upper metal wiring layer 150 selected from the plurality of upper metal wiring layers 150 may each be shifted by the same distance S1 in the first horizontal direction (the X direction) as indicated by the arrow A1. In addition, the plurality of conductive contact plugs VC2 connected to another upper metal wiring layer 150 selected from the plurality of upper metal wiring layers 150 may each be shifted by the same distance S2 in the direction (the −X direction) opposite to the first horizontal direction (the X direction) as indicated by the arrow A2.

As described above, in the integrated circuit device 100 shown in FIGS. 1 and 2, the center C1A or C1B of the uppermost portion AT, which is farthest from the substrate 110, of the upper contact portion UVC of each of the plurality of conductive contact plugs VC1 and the plurality of conductive contact plugs VC2 is shifted in the horizontal direction (for example, the X direction, the −X direction, the Y direction, or the −Y direction) from the center C1 (that is, the reference center) of the lowermost portion BT closest to the substrate 110, and the lower contact portion LVC of each of the plurality of conductive contact plugs VC1 and the plurality of conductive contact plugs VC2 may extend in diagonal direction from the upper contact portion UVC toward the lower metal wiring layer 130 corresponding to each conductive contact plug. Therefore, a separation distance between a pair of upper contact portions UVC, which are respectively included in a pair of conductive contact plugs VC1 and VC2 adjacent to each other from among the plurality of conductive contact plugs VC1 and VC2, may be increased, whereby an insulating margin between the pair of upper contact portions UVC may be secured and the lower contact portion LVC of each of the pair of conductive contact plugs VC1 and VC2 may be aligned on the lower metal wiring layer 130, which corresponds to each conductive contact plug, with high accuracy. Therefore, the reliability of electrical connection between the lower metal wiring layer 130 and the upper metal wiring layer 150 through the conductive contact plug VC1 or VC2 may increase. Therefore, the reliability of the integrated circuit device 100 including the plurality of conductive contact plugs VC1 and VC2 may increase.

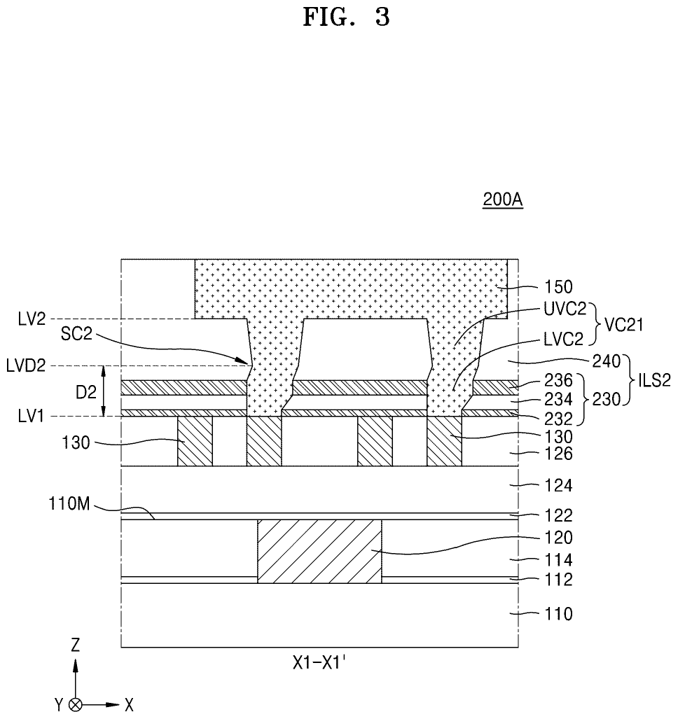

FIG. 3 is a schematic cross-sectional view of an integrated circuit device 200A according to embodiments of the present inventive concept. In FIG. 3, the same reference numerals as in FIGS. 1 and 2 respectively denote the same members, and here, repeated descriptions thereof are omitted or briefly described.

Referring to FIG. 3, the integrated circuit device 200A has substantially the same configuration as the integrated circuit device 100 described with reference to FIGS. 1 and 2. However, the integrated circuit device 200A includes an upper insulating structure ILS2, which includes an etch stop film 230 and an upper insulating film 240, and a plurality of conductive contact plugs VC21 passing through the upper insulating structure ILS2.

Each of the plurality of conductive contact plugs VC21 may be in contact with the upper metal wiring layer 150 and the lower metal wiring layer 130 both corresponding thereto. Each of the plurality of conductive contact plugs VC21 may be integrally connected to the upper metal wiring layer 150 corresponding thereto.

As each of the plurality of conductive contact plugs VC21 gets closer to the substrate 110 from the upper metal wiring layer 150 corresponding thereto, a central-axis extension direction of each of the plurality of conductive contact plugs VC21 may vary. For example, in each of the plurality of conductive contact plugs VC21, a first central axis of an upper contact portion UVC2 that is adjacent to the upper metal wiring layer 150 may extend in the vertical direction (the Z direction), and in each of the plurality of conductive contact plugs VC21, at least a portion of a lower contact portion LVC2 adjacent to the lower metal wiring layer 130 may extend in a direction that is inclined or slanted with respect to the first central axis of the upper contact portion UVC2.

In the upper insulating structure ILS2 of the integrated circuit device 200A, the etch stop film 230 may have a multilayered structure that includes a first insulating film 232 including a metal, a second insulating film 234 including no metal, and a third insulating film 236 including a metal. The second insulating film 234 may cover the upper surface of the first insulating film 232, and the third insulating film 236 may cover the upper surface of the second insulating film 234. In embodiments of the present inventive concept, each of the first insulating film 232 and the third insulating film 236 may include an aluminum oxide film, an aluminum nitride film, or a combination thereof. For example, each of the first insulating film 232 and the third insulating film 236 may include an aluminum oxide film, an aluminum nitride film, or a combination thereof. The second insulating film 234 may include, for example, a silicon oxide film, an SiOC film, or a combination thereof. In the vertical direction (the Z direction), the thickness of the first insulating film 232 may be different from the thickness of the third insulating film 236. In embodiments of the present inventive concept, in the vertical direction (the Z direction), the respective thicknesses of the first insulating film 232, the second insulating film 234, and the third insulating film 236 may be different from one another. For example, the thickness of the third insulating film 236 may be greater than the thickness of the first insulating film 232. However, the present inventive concept is not limited thereto, and each of the first insulating film 232, the second insulating film 234, and the third insulating film 236 may have various thicknesses. In the upper insulating structure ILS2 of the integrated circuit device 200A, a constituent material of the upper insulating film 240 is the same as the constituent material of the upper insulating film 140 described with reference to FIG. 2.

The sidewall of each of the plurality of conductive contact plugs VC21 may include a slope change portion SC2, which has a change in the slope of the sidewall, between the upper contact portion UVC2 and the lower contact portion LVC2. A vertical level LVD2 of the slope change portion SC2 of each of the plurality of conductive contact plugs VC21 may be higher than the first vertical level LV1 of the upper surface of each of the plurality of lower metal wiring layers 130 and lower than the second vertical level LV2 of the lower surface of each of the plurality of upper metal wiring layers 150. A vertical distance D2 from the first vertical level LV1 of the upper surface of each lower metal wiring layer 130 to the vertical level LVD2 of the slope change portion SC2 of each of the plurality of conductive contact plugs VC21 may be greater than 0 and less than the difference between the second vertical level LV2 of the lower surface of each upper metal wiring layer 150 and the first vertical level LV1 of the upper surface of each lower metal wiring layer 130.

A portion of each of the plurality of conductive contact plugs VC21 may pass through the etch stop film 230. In each of the plurality of conductive contact plugs VC21, a first inclination of a surface of the lower contact portion LVC2, which faces the upper insulating film 240, may be different from a second inclination of a surface of the lower contact portion LVC2, which faces the third insulating film 236 of the etch stop film 230. The first inclination and the second inclination may change with respect to each other at the boundary between the etch stop film 230 and the upper insulating film 240. The boundary between the etch stop film 230 and the upper insulating film 240 may correspond to the slope change portion SC2.

In embodiments of the present inventive concept, in each of the plurality of conductive contact plugs VC21, the inclination of a surface of the lower contact portion LVC2, which faces the first insulating film 232 of the etch stop film 230, the inclination of a surface of the lower contact portion LVC2, which faces the second insulating film 234 of the etch stop film 230, and the inclination of a surface of the lower contact portion LVC2, which faces the third insulating film 236 of the etch stop film 230, may be different from one another. In embodiments of the present inventive concept, in each of the plurality of conductive contact plugs VC21, the inclination of the surface of the lower contact portion LVC2, which faces the first insulating film 232 of the etch stop film 230, may be equal or similar to the inclination of the surface of the lower contact portion LVC2, which faces the third insulating film 236 of the etch stop film 230, and the inclination of the surface of the lower contact portion LVC2, which faces the second insulating film 234 of the etch stop film 230, may be different from the inclination of the surface of the lower contact portion LVC2, which faces each of the first insulating film 232 and the third insulating film 236. For example, in each of the plurality of conductive contact plugs VC21, the inclination of the surface of the lower contact portion LVC2, which faces the second insulating film 234 of the etch stop film 230, may be different from the inclination of the surface of the lower contact portion LVC2, which faces the third insulating film 236 of the etch stop film 230.

In embodiments of the present inventive concept, in each of the plurality of conductive contact plugs VC21, inclined directions of the surfaces of the lower contact portion LVC2, which respectively face the first insulating film 232 and the third insulating film 236 of the etch stop film 230, may be closer to the vertical direction (the Z direction) than an inclined direction of each of the surfaces of the lower contact portion LVC2, which respectively face the second insulating film 234 of the etch stop film 230 and the upper insulating film 240.

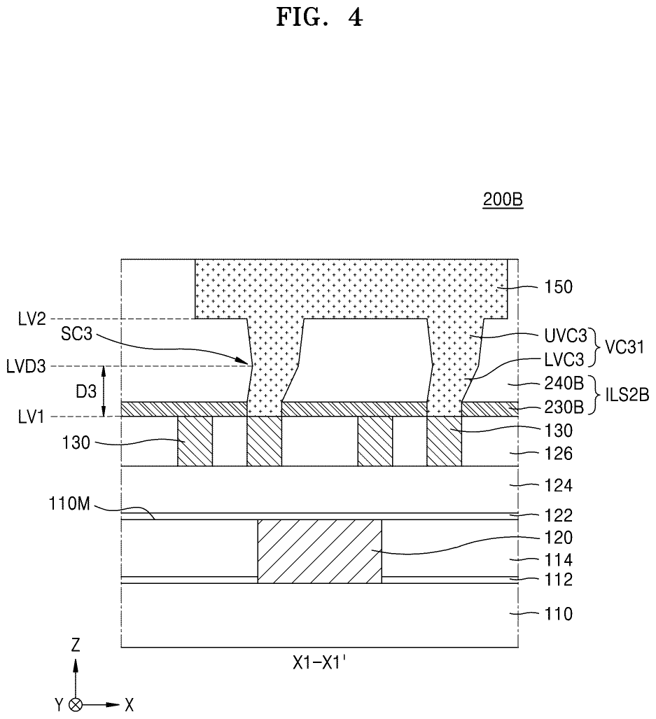

FIG. 4 is a schematic cross-sectional view of an integrated circuit device 200B according to embodiments of the present inventive concept. In FIG. 4, the same reference numerals as in FIGS. 1 and 2 respectively denote the same members, and here, repeated descriptions thereof are omitted or briefly described.

Referring to FIG. 4, the integrated circuit device 200B has substantially the same configuration as the integrated circuit device 100 described with reference to FIGS. 1 and 2. However, the integrated circuit device 200B includes an upper insulating structure ILS2B, which includes an etch stop film 230B and an upper insulating film 240B, and a plurality of conductive contact plugs VC31 passing through the upper insulating structure ILS2B.

Each of the plurality of conductive contact plugs VC31 may be in contact with the corresponding upper metal wiring layer 150 and the corresponding lower metal wiring layer 130. Each of the plurality of conductive contact plugs VC31 may be integrally connected to the corresponding upper metal wiring layer 150.

As each of the plurality of conductive contact plugs VC31 gets closer to the substrate 110 from the corresponding upper metal wiring layer 150, a central-axis extension direction of each of the plurality of conductive contact plugs VC31 may vary. For example, in each of the plurality of conductive contact plugs VC31, a first central axis of an upper contact portion UVC3 adjacent to the upper metal wiring layer 150 may extend in the vertical direction (the Z direction), and in each of the plurality of conductive contact plugs VC31, at least a portion of a lower contact portion LVC3 adjacent to the lower metal wiring layer 130 may extend in a direction that is inclined or slanted with respect to the first central axis of the upper contact portion UVC3.

In the upper insulating structure ILS2B of the integrated circuit device 200B, the etch stop film 230B may have a single-layered structure including a metal-containing insulating film. For example, the etch stop film 230B may include an aluminum oxide film, an aluminum nitride film, or a combination thereof. A constituent material of the upper insulating film 240B is the same as the constituent material of the upper insulating film 140 described with reference to FIG. 2.

The sidewall of each of the plurality of conductive contact plugs VC31 may include a slope change portion SC3, which has a change in the slope of the sidewall, between the upper contact portion UVC3 and the lower contact portion LVC3. A vertical level LVD3 of the slope change portion SC3 of each of the plurality of conductive contact plugs VC31 may be higher than the first vertical level LV1 of the upper surface of each of the plurality of lower metal wiring layers 130 and lower than the second vertical level LV2 of the lower surface of each of the plurality of upper metal wiring layers 150. A vertical distance D3 from the first vertical level LV1 of the upper surface of each lower metal wiring layer 130 to the vertical level LVD3 of the slope change portion SC3 of each of the plurality of conductive contact plugs VC31 may be greater than 0 and less than the difference between the second vertical level LV2 of the lower surface of each upper metal wiring layer 150 and the first vertical level LV1 of the upper surface of each lower metal wiring layer 130.

A portion of each of the plurality of conductive contact plugs VC31 may pass through the etch stop film 230B. In each of the plurality of conductive contact plugs VC31, a first inclination of a surface of the lower contact portion LVC3, which faces the upper insulating film 240B, may be different from a second inclination of a surface of the lower contact portion LVC3, which faces the etch stop film 230B. For example, the first inclination of the surface of the lower contact portion LVC3 may be disposed in the upper insulating film 240B, and the second inclination of the surface of the lower contact portion LVC3 may be disposed in the etch stop film 230B. The first inclination and the second inclination may change with respect to each other at the boundary between the etch stop film 230B and the upper insulating film 240B. The boundary between the etch stop film 230B and the upper insulating film 240B may correspond to the slope change portion SC3.

In embodiments of the present inventive concept, in each of the plurality of conductive contact plugs VC31, inclined directions of surfaces of the lower contact portion LVC3, which face the etch stop film 230B, may be closer to the vertical direction (the Z direction) than an inclined direction of the lower contact portion LVC3, which faces the upper insulating film 240B.

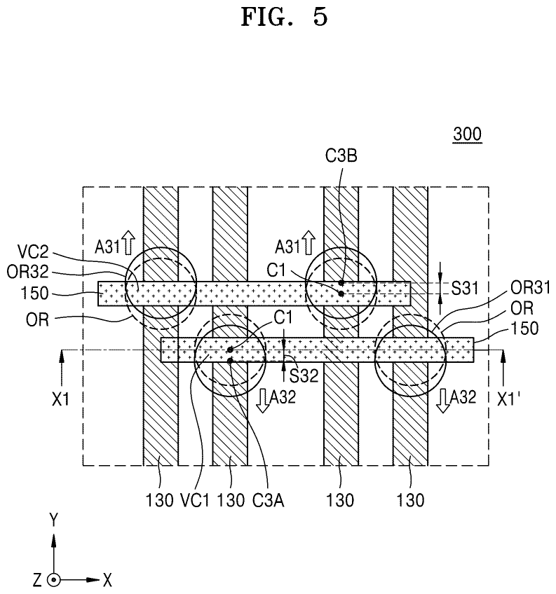

FIG. 5 is a schematic cross-sectional view of an integrated circuit device 300 according to embodiments of the present inventive concept. In FIG. 5, the same reference numerals as in FIGS. 1 and 2 respectively denote the same members, and here, repeated descriptions thereof are omitted or briefly discussed.

Referring to FIG. 5, the integrated circuit device 300 has substantially the same configuration as the integrated circuit device 100 described with reference to FIGS. 1 and 2. However, in the integrated circuit device 300, in each of the plurality of conductive contact plugs VC1 and VC2, a center C3A of the uppermost portion (corresponding to the uppermost portion AT shown in FIG. 2) farthest from the substrate 110 may be shifted in the second horizontal direction (the Y direction) or the direction (the −Y direction) opposite to the second horizontal direction (the Y direction), from the center C1 of the lowermost portion (corresponding to the lowermost portion BT shown in FIG. 2) closest to the substrate 110. In the viewpoint of a plane (the X-Y plane in FIG. 5), the uppermost portion (corresponding to the uppermost portion AT shown in FIG. 2) of each of the plurality of conductive contact plugs VC1 and VC2 may be arranged at a position shifted in the second horizontal direction (the Y direction) or the direction (the −Y direction) opposite to the second horizontal direction (the Y direction) from the imaginary reference overlay circle OR having, as the center thereof, the center C1 (that is, the reference center) of the lowermost portion (corresponding to the lowermost portion BT shown in FIG. 2) of each of the plurality of conductive contact plugs VC1 and VC2.

FIG. 5 illustrates that, in some conductive contact plugs VC2 selected from the plurality of conductive contact plugs VC1 and VC2, the center C3B of the uppermost portion AT farthest from the substrate 110 is shifted by a distance S31 greater than 0 in the second horizontal direction (the Y direction) as indicated by the arrow A31 from the center C1 (that is, the reference center) of the lowermost portion BT, in the viewpoint of a plane (the X-Y plane in FIG. 5). In addition, FIG. 5 also illustrates that, in some other conductive contact plugs VC1 selected from the plurality of conductive contact plugs VC1 and VC2, the center C3A of the uppermost portion AT farthest from the substrate 110 is shifted by a distance S32 greater than 0 in the direction (the −Y direction) opposite to the second horizontal direction (the Y direction) as indicated by the arrow A32 from the center C1 (that is, the reference center) of the lowermost portion BT, in the viewpoint of a plane (the X-Y plane in FIG. 5).

In embodiments of the present inventive concept, the plurality of conductive contact plugs VC2 connected to one upper metal wiring layer 150 selected from the plurality of upper metal wiring layers 150 may each be shifted by the same distance S31 in the second horizontal direction (the Y direction) as indicated by the arrow A31. In addition, the plurality of conductive contact plugs VC1 connected to another upper metal wiring layer 150 selected from the plurality of upper metal wiring layers 150 may each be shifted by the same distance S32 in the direction (the −Y direction) opposite to the second horizontal direction (the Y direction) as indicated by the arrow A32.

According to the integrated circuit devices 200A, 200B, and 300 described with reference to FIGS. 3 to 5, similar to the integrated circuit device 100 described with reference to FIGS. 1 and 2, in each of a plurality of conductive contact plugs VC1, VC21, and VC31 and a plurality of conductive contact plugs VC2, the center of the uppermost portion, which is farthest from the substrate 110, of the upper contact portion UVC, UVC2, or UVC3 may be shifted in the horizontal direction (for example, the X direction, the −X direction, the Y direction, or the −Y direction) from the center (that is, the reference center) of the lowermost portion closest to the substrate 110, and the lower contact portion LVC, LVC2, or LVC3 of each of the plurality of conductive contact plugs VC1, VC21, and VC31 and the plurality of conductive contact plugs VC2 may extend in an inclined or diagonally direction from the upper contact portion UVC, UVC2, or UVC3 toward the corresponding lower metal wiring layer 130. Therefore, a separation distance between a pair of upper contact portions (that is, UVC, UVC2, or UVC3), which are respectively included in a pair of conductive contact plugs adjacent to each other from among a plurality of conductive contact plugs VC1, VC21, and VC31, may be increased, whereby an insulating margin between the pair of upper contact portions may be secured and the lower contact portion LVC, LVC2, or LVC3 of each of the pair of conductive contact plugs (that is, VC1, VC21, or VC31) may be aligned on the corresponding lower metal wiring layer 130 with high accuracy. Therefore, the reliability of electrical connection between the lower metal wiring layer 130 and the upper metal wiring layer 150 through the conductive contact plug VC1, VC21, or VC31 may increase. Therefore, the reliability of each of the integrated circuit devices 200A, 200B, and 300 respectively including the plurality of conductive contact plugs VC1, VC21, and VC31 may increase.

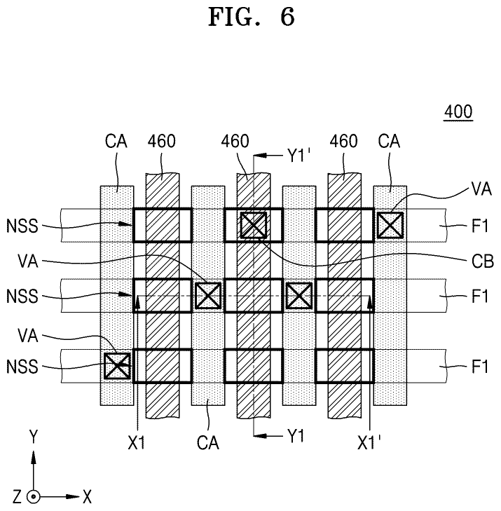

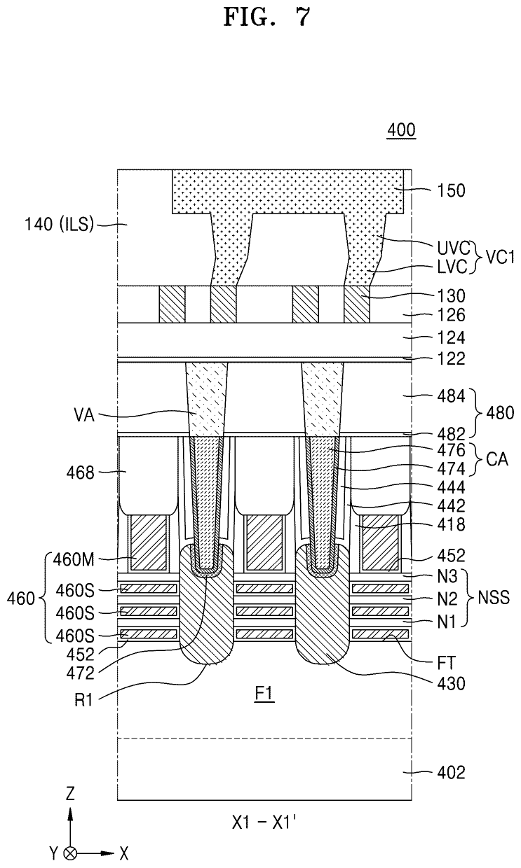

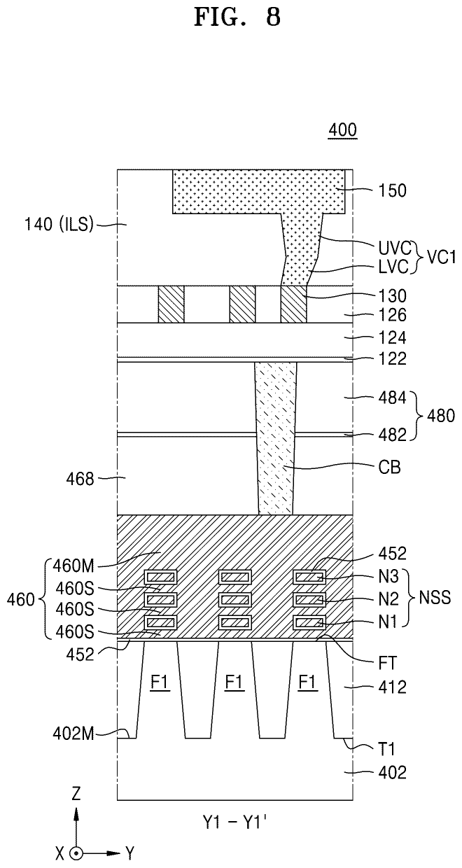

FIG. 6 is a planar layout diagram illustrating an integrated circuit device 400 according to embodiments of the present inventive concept. FIG. 7 is a cross-sectional view of the integrated circuit device 400, taken along the line X1-X1′ of FIG. 6. FIG. 8 is a cross-sectional view of the integrated circuit device 400, taken along the line Y1-Y1 of FIG. 6. The integrated circuit device 400 including a field-effect transistor, which has a gate-all-around structure including an active region with a nanowire or nanosheet shape and a gate surrounding the active region, is described with reference to FIGS. 6 to 8. In FIGS. 6 to 8, the same reference numerals as in FIGS. 1 and 2 respectively denote the same members, and here, repeated descriptions thereof are omitted or briefly described.

Referring to FIGS. 6 to 8, the integrated circuit device 400 may include a plurality of fin-type active regions F1, which protrude from a substrate 402 and extend lengthwise in the first horizontal direction (the X direction), and a plurality of nanosheet stacks NSS, which are disposed on a fin top surface FT of each of the plurality of fin-type active regions F1 while upwardly spaced apart from the plurality of fin-type active regions F1 in the vertical direction (the Z direction). As used herein, the term “nanosheet” refers to a conductive structure having a cross-section that is substantially perpendicular to a current-flowing direction. The nanosheet may be understood as including a nanowire.

A trench T1 may be formed in the substrate 402 to define the plurality of fin-type active regions F1 and may be filled with a device isolation film 412. The substrate 402 may include a semiconductor, such as Si or Ge, or a compound semiconductor, such as SiGe, SiC, GaAs, InAs, InGaAs, or InP. The substrate 402 may include a conductive region, for example, an impurity-doped well or an impurity-doped structure. The device isolation film 412 may include an oxide film, a nitride film, or a combination thereof.

A plurality of gate lines 460 may be arranged on the plurality of fin-type active regions F1. Each of the plurality of gate lines 460 may extend lengthwise in the second horizontal direction (the Y direction) intersecting with the first horizontal direction (the X direction).

In intersection areas between the plurality of fin-type active regions F1 and the plurality of gate lines 460, the plurality of nanosheet stacks NSS may be arranged over the fin top surface FT of each of the plurality of fin-type active regions F1. Each of the plurality of nanosheet stacks NSS may include at least one nanosheet arranged spaced apart from the fin top surface FT of the fin-type active region F1 in the vertical direction (the Z direction) and facing the fin top surface FT of the fin-type active region F1.

In embodiments of the present inventive concept, each of the plurality of nanosheet stacks NSS may include a first nanosheet N1, a second nanosheet N2, and a third nanosheet N3, which overlap each other in the vertical direction (Z direction), on the fin-type active region F1. Each of the plurality of gate lines 460 may surround the first nanosheet N1, the second nanosheet N2, and the third nanosheet N3, which are included in a nanosheet stack NSS and overlap each other in the vertical direction (the Z direction).

Each of the plurality of gate lines 460 may include a main gate portion 460M and a plurality of sub-gate portions 460S. The main gate portion 460M may extend lengthwise in the second horizontal direction (the Y direction) and cover the upper surface of the nanosheet stack NSS. The plurality of sub-gate portions 460S may be integrally connected to the main gate portion 460M and may be respectively arranged one-by-one between the first nanosheet N1, the second nanosheet N2, and the third nanosheet N3 and between the first nanosheet N1 and the fin-type active region F1. In the vertical direction (the Z direction), the thickness of each of the plurality of sub-gate portions 460S may be less than the thickness of the main gate portion 460M.

A plurality of recesses R1 may be formed in the fin-type active region F1. A vertical level of the lowermost surface of each of the plurality of recesses R1 may be lower than a vertical level of the fin top surface FT of the fin-type active region F1. A plurality of source/drain regions 430 may be respectively arranged in the plurality of recesses R1. Each of the plurality of source/drain regions 430 may be arranged adjacent to at least one gate line 460 selected from the plurality of gate lines 460. Each of the plurality of source/drain regions 430 may be adjacent to the first nanosheet N1, the second nanosheet N2, and the third nanosheet N3, which are included in the nanosheet stack NSS. For example, each of the plurality of source/drain regions 430 may be in contact with the first nanosheet N1, the second nanosheet N2, and the third nanosheet N3, which are included in the nanosheet stack NSS adjacent thereto.

Each of the plurality of gate lines 460 may include, for example, a metal, a metal nitride, a metal carbide, or a combination thereof. The metal may be at least one of, for example, Ti, W, Ru, Nb, Mo, Hf, Ni, Co, Pt, Yb, Tb, Dy, Er, and/or Pd. The metal nitride may be at least one of, for example, TiN and/or TaN. The metal carbide may include TiAlC. However, a material constituting the plurality of gate lines 460 is not limited to the examples set forth above. Each of the plurality of gate lines 460 may further include a gap-fill metal film. The gap-fill metal film may include, for example, a W film or an Al film. In embodiments of the present inventive concept, each of the plurality of gate lines 460 may include, but is not limited to, a TiN film, a stack structure of TiAlC/TiN/W, a stack structure of TiN/TaN/TiAlC/TiN/W, or a stack structure of TiN/TaN/TiN/TiAlC/TiN/W.

A gate dielectric film 452 may be arranged between the nanosheet stack NSS and the gate line 460. In embodiments of the present inventive concept, the gate dielectric film 452 may include a stack structure of an interface dielectric film and a high-K film. The interface dielectric film may include a low-K material film having a dielectric constant of about 9 or less, for example, a silicon oxide film, a silicon oxynitride film, or a combination thereof. In embodiments of the present inventive concept, the interface dielectric film may be omitted. The high-K film may include a material having a dielectric constant that is greater than that of a silicon oxide film. For example, the high-K film may have a dielectric constant of about 10 to about 25. The high-K film may include, but is not limited to, hafnium oxide.

Both sidewalls of the gate line 460 may be covered by an insulating spacer 418. The insulating spacer 418 may be arranged on the upper surface of each of the plurality of nanosheet stacks NSS and cover both sidewalls of the main gate portion 460M. The insulating spacer 418 may be spaced apart from the gate line 460 with the gate dielectric film 452 therebetween. The insulating spacer 418 may include, for example, silicon nitride, silicon oxide, SiCN, SiBN, SiON, SiOCN, SiBCN, SiOC, or a combination thereof.

The upper surface of each of the gate dielectric film 452, the gate line 460, and the insulating spacer 418 may be covered by a capping insulating pattern 468. For example, the capping insulating pattern 468 may be in contact with the upper surface of each of the gate dielectric film 452, the gate line 460, and the insulating spacer 418. The capping insulating pattern 468 may include, for example, a silicon nitride film.

Either sidewall of each of the plurality of sub-gate portions 460S may be spaced apart from the source/drain region 430 with the gate dielectric film 452 therebetween. The gate dielectric film 452 may be arranged between a sub-gate portion 460S of the gate line 460 and each of the first nanosheet N1, the second nanosheet N2, and the third nanosheet N3 and between the sub-gate portion 460S of the gate line 460 and the source/drain region 430.

A plurality of nanosheet transistors may be respectively formed on the substrate 402 and in the intersection areas that are formed between the plurality of fin-type active regions F1 and the plurality of gate lines 460. Each of the first nanosheet N1, the second nanosheet N2, and the third nanosheet N3 of the nanosheet stack NSS may have a channel region. In embodiments of the present inventive concept, each of the first nanosheet N1, the second nanosheet N2, and the third nanosheet N3 of the nanosheet stack NSS may include a Si layer, a SiGe layer, or a combination thereof.

A metal silicide film 472 may be formed on the upper surface of each of the plurality of source/drain regions 430. For example, the metal silicide film 472 may include a metal including Ti, W, Ru, Nb, Mo, Hf, Ni, Co, Pt, Yb, Tb, Dy, Er, or Pd. For example, the metal silicide film 472 may include, but is not limited to, titanium silicide.

An insulating liner 442 and an inter-gate dielectric 444 may be arranged in the stated order on the plurality of source/drain regions 430 and a plurality of metal silicide films 472. In embodiments of the present inventive concept, the insulating liner 442 may include, but is not limited to, silicon nitride (SiN), SiCN, SiBN, SiON, SiOCN, SiBCN, or a combination thereof.

A plurality of source/drain contacts CA may be respectively arranged on the plurality of source/drain regions 430. Each of the plurality of source/drain contacts CA may pass through the inter-gate dielectric 444 and the insulating liner 442 in the vertical direction (the Z direction) and thus be in contact with the metal silicide film 472. Each of the plurality of source/drain contacts CA may be configured to be electrically connected to the source/drain region 430 via the metal silicide film 472. Each of the plurality of source/drain contacts CA may be spaced apart from the main gate portion 460M in the first horizontal direction (the X direction) with the insulating spacer 418 therebetween.

Each of the plurality of source/drain contacts CA may include a conductive barrier film 474 and a contact plug 476, which are stacked in the stated order on the metal silicide film 472. The conductive barrier film 474 may at least partially surround and contact the lower surface and the sidewall of the contact plug 476. In embodiments of the present inventive concept, the conductive barrier film 474 may include a metal or a metal nitride. For example, the conductive barrier film 474 may include, but is not limited to, Ti, Ta, W, TiN, TaN, WN, WCN, TiSiN, TaSiN, WSiN, or a combination thereof. For example, the contact plug 476 may include at least one of molybdenum (Mo), copper (Cu), tungsten (W), cobalt (Co), ruthenium (Ru), manganese (Mn), titanium (Ti), tantalum (Ta), aluminum (Al), or a combination thereof.

A lower insulating structure 480 may be arranged on the respective upper surfaces of the plurality of source/drain contacts CA and a plurality of capping insulating patterns 468. The lower insulating structure 480 may include a lower etch stop film 482 and a first interlayer dielectric 484, which are stacked in the stated order on the upper surface of each of the plurality of capping insulating patterns 468. The lower etch stop film 482 may include, for example, silicon carbide (SiC), SiN, nitrogen-doped silicon carbide (SiC:N), SiOC, AlN, AlON, AlO, AlOC, or a combination thereof. A constituent material of the first interlayer dielectric 484 is substantially the same as the constituent material of the first interlayer dielectric 114 described with reference to FIG. 2.

As shown in FIG. 7, a plurality of source/drain via contacts VA may be respectively arranged on the plurality of source/drain contacts CA. Each of the plurality of source/drain via contacts VA may pass through the lower insulating structure 480 and be in contact with a corresponding source/drain contact CA. Each of the plurality of source/drain regions 430 may be configured to be electrically connected to a source/drain via contact VA through the metal silicide film 472 and the source/drain contact CA.

As shown in FIG. 8, a gate contact CB may be arranged on the gate line 460. The gate contact CB may be configured to pass through the lower insulating structure 480 and the capping insulating pattern 468 in the vertical direction (Z direction) and be connected to the gate line 460.

Each of the plurality of source/drain via contacts VA and the gate contact CB may include a contact plug including, for example, molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof, but a constituent material of the contact plug is not limited to the examples set forth above. In embodiments of the present inventive concept, each of the plurality of source/drain via contacts VA and the gate contact CB may further include a conductive barrier pattern at least partially surrounding a portion of the contact plug. The conductive barrier pattern, which is included in each of the plurality of source/drain via contacts VA and the gate contact CB, may include a metal or a metal nitride. For example, the conductive barrier pattern may include, but is not limited to, Ti, Ta, W, TiN, TaN, WN, WCN, TiSiN, TaSiN, WSiN, or a combination thereof.

A lower etch stop film 122 and a second interlayer dielectric 124 may be stacked in the stated order on each of the lower insulating structure 480, the source/drain via contact VA, and the gate contact CB, and a wiring structure, which includes a lower insulating film 126, a plurality of lower metal wiring layers 130, an upper insulating film 140, an upper metal wiring layer 150, and a plurality of conductive contact plugs VC1 passing through the upper insulating film 140, may be arranged on the second interlayer dielectric 124. The detailed configuration and effects of the wiring structure are the same as described with reference to FIGS. 1 and 2.

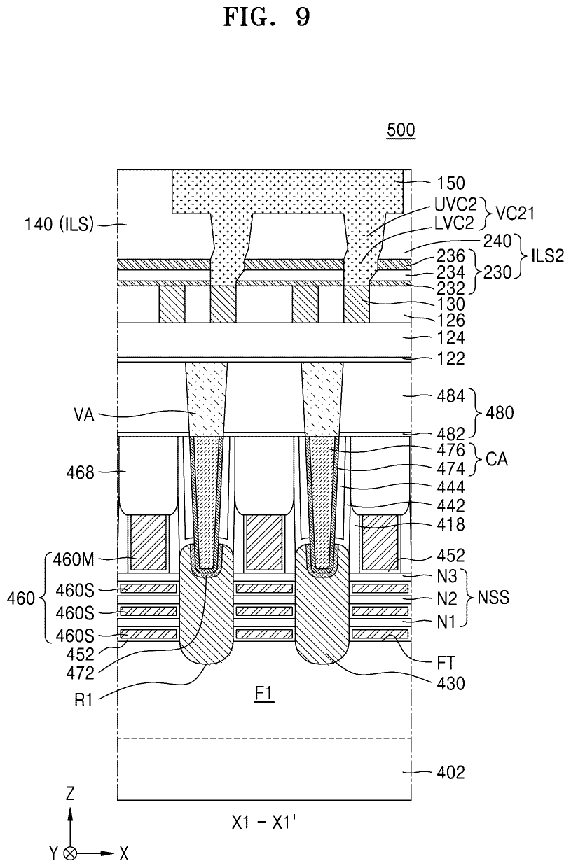

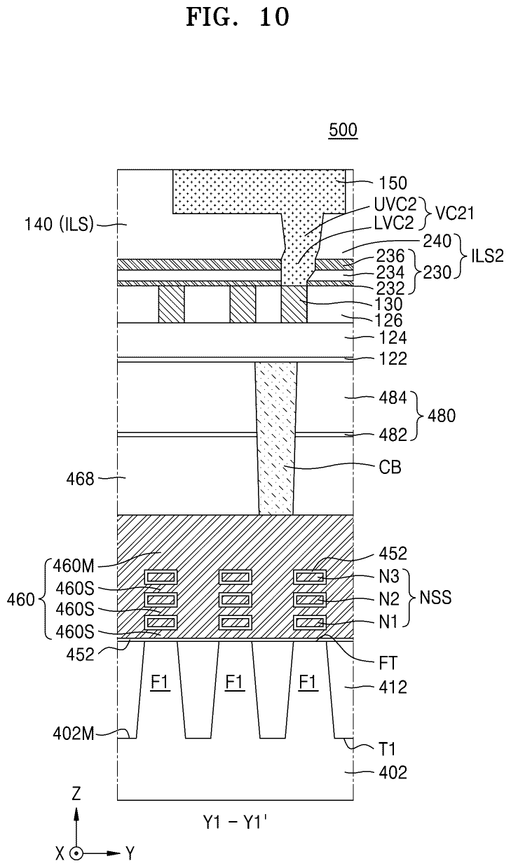

FIGS. 9 and 10 are cross-sectional views illustrating an integrated circuit device 500 according to embodiments of the present inventive concept. FIG. 9 illustrates components in a portion of the integrated circuit device 500, which corresponds to the cross-section taken along the line X1-X1′ of FIG. 6, and FIG. 10 illustrates components in a portion of the integrated circuit device 500, which corresponds to the cross-section taken along the line Y1-Y1′ of FIG. 6. In FIGS. 9 and 10, the same reference numerals as in FIGS. 1, 2, and 6 to 8 respectively denote the same members, and here, repeated descriptions thereof are omitted or briefly described.

Referring to FIGS. 9 and 10, the integrated circuit device 500 has substantially the same configuration as the integrated circuit device 400 described with reference to FIGS. 6 to 8. However, the integrated circuit device 500 may include a wiring structure including the lower insulating film 126, the plurality of lower metal wiring layers 130, the etch stop film 230, the upper insulating film 240, and the upper metal wiring layer 150, which are arranged on or over the second interlayer dielectric 124, and may also include the plurality of conductive contact plugs VC21 passing through the etch stop film 230 and the upper insulating film 240. The detailed configuration and effects of the wiring structure are the same as described with reference to FIG. 3.

According to the integrated circuit devices 400 and 500 described with reference to FIGS. 6 to 10, similar to the integrated circuit device 100 described with reference to FIGS. 1 and 2, in each of the plurality of conductive contact plugs VC1 and VC21, the center of the uppermost portion of the upper contact portion UVC or UVC2, which is farthest from the substrate 402, may be shifted in the horizontal direction (for example, the X direction, the −X direction, the Y direction, or the −Y direction), which is parallel to a main surface 402M of the substrate 402, from the center of the lowermost portion closest to the substrate 402, and the lower contact portion LVC or LVC2 of each of the plurality of conductive contact plugs VC1 and VC21 may extend in an inclined or diagonal direction from the upper contact portion UVC or UVC2 toward the lower metal wiring layer 130 corresponding to each conductive contact plug. Therefore, a separation distance between a pair of conductive contact plugs (that is, VC1 or VC21) adjacent to each other from among the plurality of conductive contact plugs VC1 and VC21 may be increased, whereby an insulating margin between the pair of conductive contact plugs (that is, VC1 or VC21) may be secured and the lower contact portion LVC or LVC2 of each of the pair of conductive contact plugs (that is, VC1 or VC21) may be aligned on the lower metal wiring layer 130, which corresponds to each conductive contact plug, with high accuracy. Therefore, the reliability of electrical connection between the lower metal wiring layer 130 and the upper metal wiring layer 150 through the conductive contact plug VC1 or VC21 may increase. Therefore, the reliability of each of the integrated circuit devices 400 and 500 respectively including the plurality of conductive contact plugs VC1 and VC21 may increase.

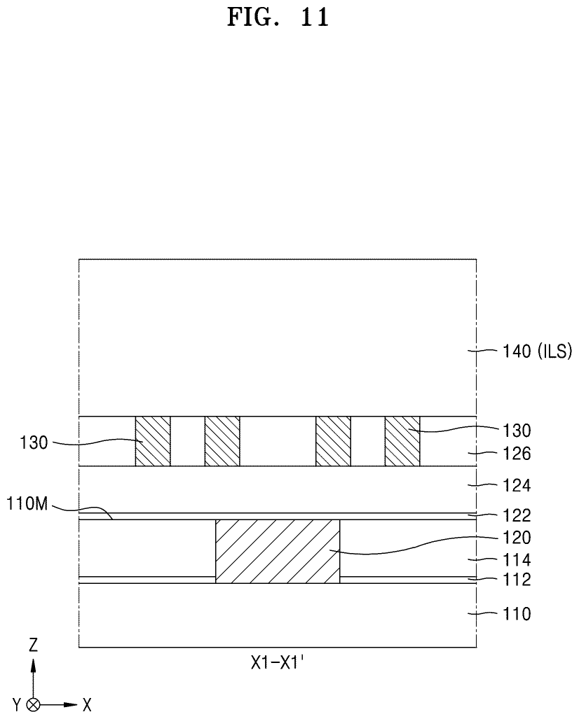

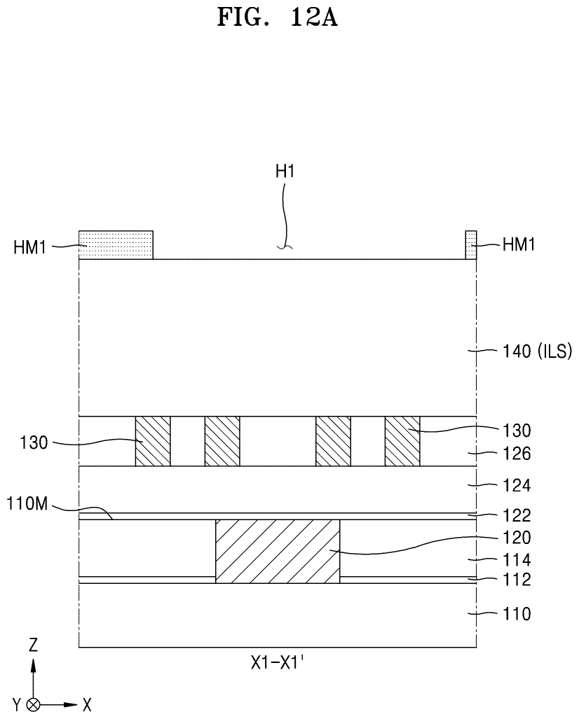

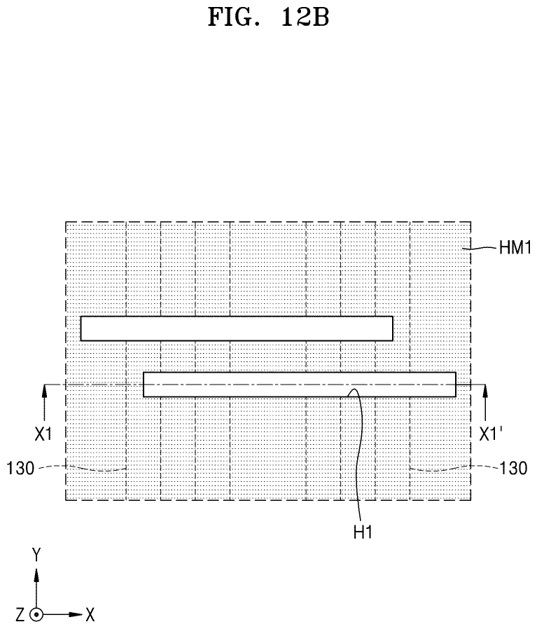

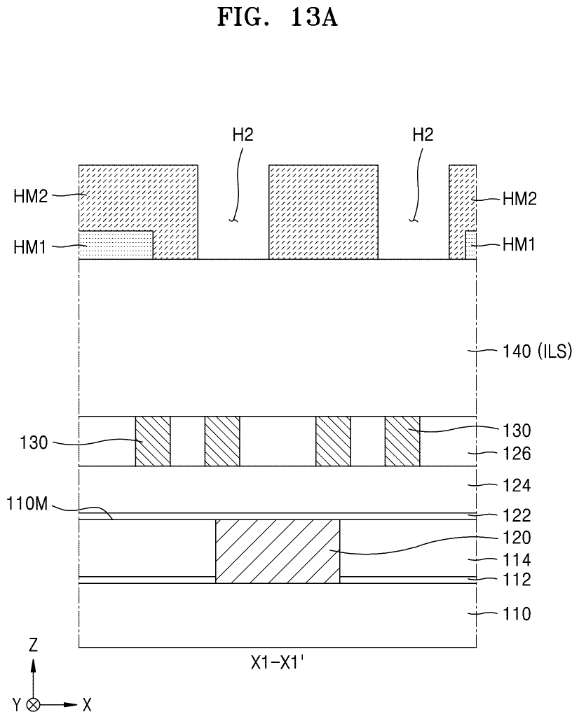

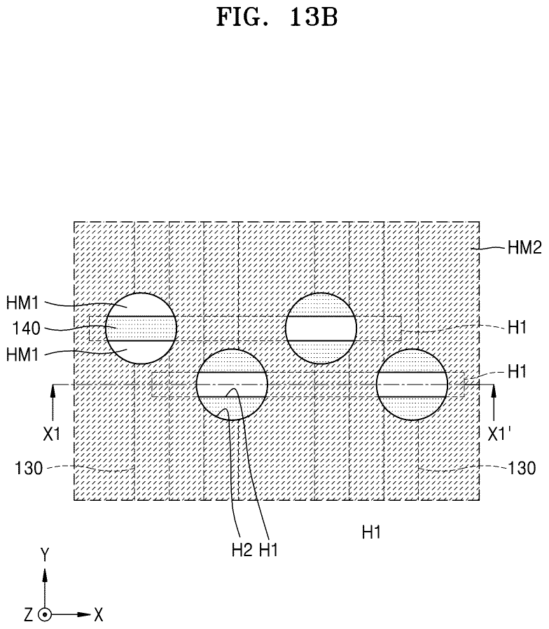

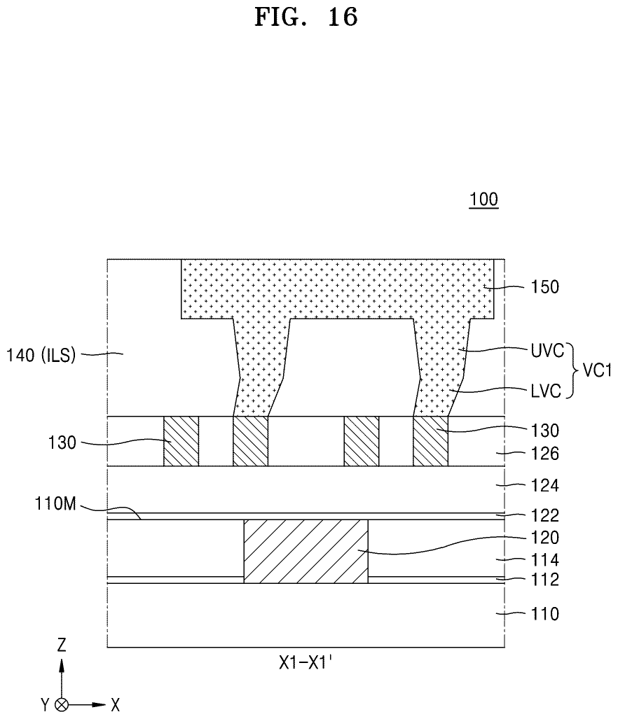

FIGS. 11, 12A, 13A, 14, 15, and 16 are cross-sectional views respectively illustrating a sequence of processes of an example of a method of fabricating an integrated circuit device, according to embodiments of the present inventive concept. FIG. 12B is a plan view illustrating the process of FIG. 12A, and FIG. 13B is a plan view illustrating the process of FIG. 13A. An example of a method of fabricating the integrated circuit device 100 shown in FIGS. 1 and 2 is described with reference to FIGS. 11 to 16. In FIGS. 11 and 16, the same reference numerals as in FIGS. 1 and 2 respectively denote the same members, and here, repeated descriptions thereof are omitted or briefly described.

Referring to FIG. 11, the first lower etch stop film 112 and the first interlayer dielectric 114 may be formed on or over the substrate 110, and the conductive structure 120 may be formed through the first interlayer dielectric 114 and the first etch stop film 112 to be electrically connectable to a conductive region of the substrate 110. To form the conductive structure 120, an opening may be formed by partially etching the first interlayer dielectric 114 and the first lower etch stop film 112, and then, conductive materials may fill the inside of the openings in the first interlayer dielectric 114 and the first lower etch stop film 112. The conductive structure 120 may be electrically connected with the conductive region formed in the substrate 110. In embodiments of the present inventive concept, the conductive structure 120 may include, but is not limited to, a source/drain region, a source/drain contact, a via contact, or a gate contact of a transistor.

The second lower etch stop film 122 and the second interlayer dielectric 124 may be formed on or over the first interlayer dielectric 114, and the lower insulating film 126 may be formed on the second interlayer dielectric 124. In addition, the plurality of lower metal wiring layers 130 may be formed to pass through the lower insulating film 126 in the vertical direction (the Z direction). Next, the upper insulating film 140 may be formed on the lower insulating film 126 and the plurality of lower metal wiring layers 130.

Referring to FIGS. 12A and 12B, a first hardmask pattern HM1 may be formed on the upper insulating film 140. The first hardmask pattern HM1 may have a plurality of openings H1 having shapes that respectively correspond to the planar shapes of the plurality of upper metal wiring layers 150 (see FIGS. 1 and 2). For example, the plurality of openings H1 may have rectangular shapes. The upper surface of the upper insulating film 140 may be exposed by the plurality of openings H1 of the first hardmask pattern HM1. The first hardmask pattern HM1 may include a multi-mask pattern including a metal-containing mask pattern and a silicon oxide mask pattern. For example, the metal-containing mask pattern may include, but is not limited to, a TiN film or a tungsten (W)-doped carbon film.

Referring to FIGS. 13A and 13B, a second hardmask pattern HM2 may be formed on the resulting product of FIGS. 12A and 12B. The second hardmask pattern HM2 may have a plurality of openings H2. The plurality of openings H2 may have planar shapes respectively corresponding to the imaginary overlay circles OR1 and OR2 shown in FIGS. 1 and 2. For example, the plurality of openings H2 may have circular shapes. The upper surface of the upper insulating film 140 and the upper surface of the first hardmask pattern HM1 may be exposed by the plurality of openings H2 of the second hardmask pattern HM2. For example, the second hardmask pattern HM2 may include, but is not limited to, a spin-on-hardmask (SOH) mask pattern, a silicon oxide mask pattern, or a photoresist pattern.

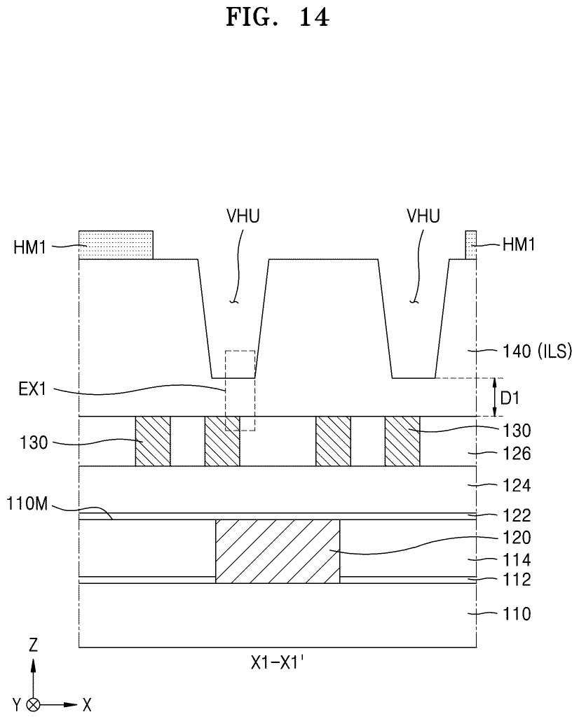

Referring to FIG. 14, in the resulting product of FIGS. 13A and 13B, the upper insulating film 140 may be etched by as much as a certain thickness by using the first hardmask pattern HM1 and the second hardmask pattern HM2 as an etch mask, thereby forming a plurality of upper via holes VHU in the upper insulating film 140. Next, the second hardmask pattern HM2 may be removed.

After the plurality of upper via holes VHU are formed, the lower surface of each of the plurality of upper via holes VHU may be separated by as much as a vertical distance D1 from the upper surface of each of the plurality of lower metal wiring layers 130. In embodiments of the present inventive concept, the thickness, which corresponds to the vertical distance D1, of the upper insulating film 140 exposed at the lower surface of each of the plurality of upper via holes VHU may be, but is not limited to, about 5 nm to about 20 nm, for example, about 8 nm to about 12 nm.

In embodiments of the present inventive concept, to form the plurality of upper via holes VHU, a plasma-enhanced atomic layer etching (PEALE) process may be used.

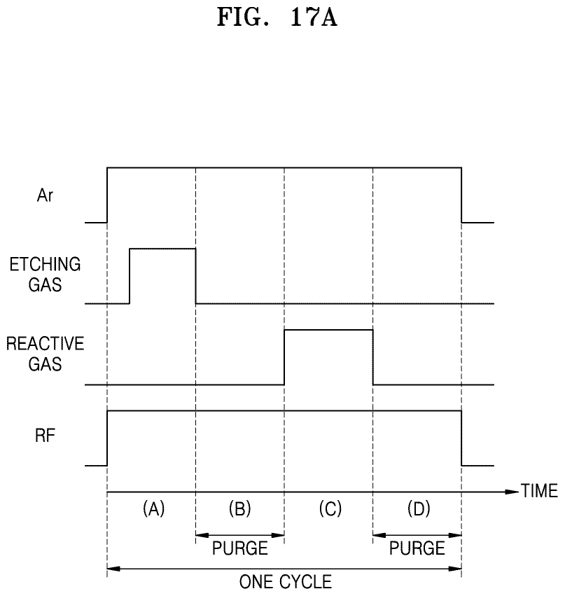

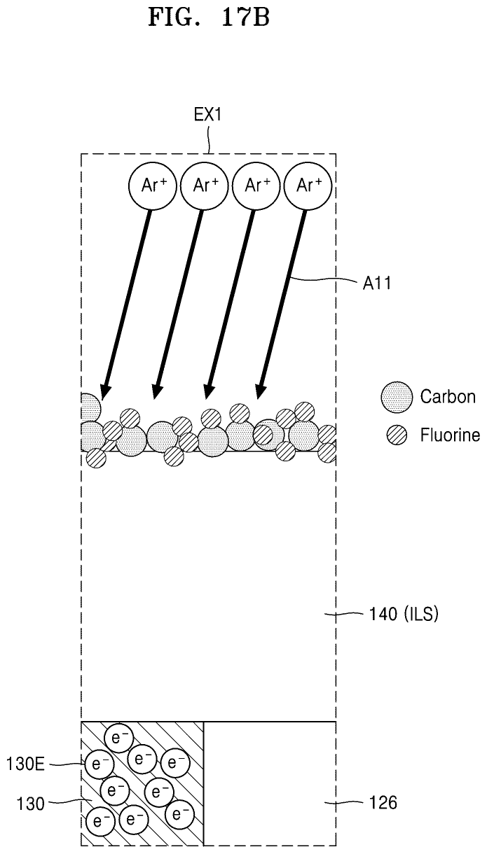

FIG. 17A is a timing pulse diagram illustrating an example of a PEALE process for etching the upper insulating film 140 to form the plurality of upper via holes VHU as described with reference to FIG. 14.

In embodiments of the present inventive concept, a process of etching the upper insulating film 140 to form the plurality of upper via holes VHU may include operation (A) of supplying an etching gas together with Argon (Ar) gas into a reaction chamber to chemisorb the etching gas in a non-excited state onto an etching target surface in the reaction chamber in which the resulting product of FIGS. 13A and 13B is loaded. The process of etching the upper insulating film 140 may further include operation (B) of purging the inside of the reaction chamber, to which the etching gas has been supplied, by using Ar gas, and operation (C) of supplying a reactive gas together with Ar gas into the reaction chamber. The process additionally includes operation (D) of purging the inside of the reaction chamber, to which the reactive gas has been supplied. In embodiments of the present inventive concept, the etching gas may include a fluorocarbon compound. For example, the etching gas may include, but is not limited to, CHF₃, CH₂F₂, CH₃F, CF₄, C₂F₆, C₄F₈, C₄F₆, or a combination thereof. The reactive gas may include, but is not limited to, O₂, CO₂, N₂O, or a combination thereof.

In operation (A) of supplying the etching gas together with Ar gas into the reaction chamber, to generate reactive species of Ar gas and bring the surface of the upper insulating film 140, on which the etching gas is chemisorbed, into contact with the reactive species of Ar gas to etch the upper insulating film 140, a pulse of RF power may be applied to the reaction chamber. In operation (C) of supplying the reactive gas together with Ar gas into the reaction chamber, to increase the etch rate of the upper insulating film 140, oxygen plasma may be generated by applying a pulse of RF power to the reaction chamber. As a result, in operation (C), sputtering of the upper insulating film 140 may be performed by using Ar+ while positively charged Ar+ does not have specific directionality. When operations (A), (B), (C), and (D) described above are taken as one PEALE cycle, a plurality of PEALE cycles may be performed.

In the PEALE process for forming the plurality of upper via holes VHU, the directionality of F⁻ radicals generated from the etching gas due to plasma generation might not be constant. In addition, positively charged Ar⁺ may not have specific directionality. As a result, while the plurality of upper via holes VHU are being formed, the upper insulating film 140 may be etched without specified directionality.

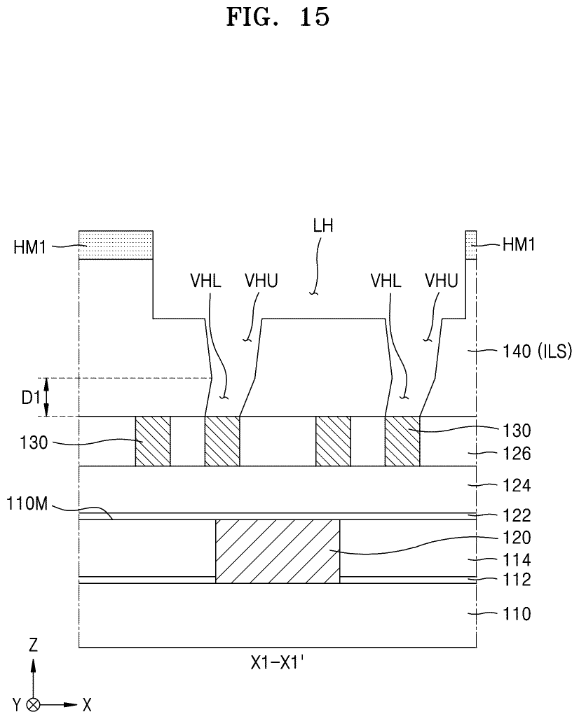

Referring to FIG. 15, in the resulting product of FIG. 14, the upper insulating film 140 that is exposed may be etched by using the first hardmask pattern HM1 as an etch mask, thereby forming an upper wiring trench LH and a plurality of lower via holes VHL. The upper wiring trench LH may be connected with the plurality of lower via holes VHL through the plurality of upper via holes VHU.

FIG. 17B is a cross-sectional view illustrating an example of a PEALE process for etching the upper insulating film 140 to form a plurality of lower via holes VHL as described with reference to FIG. 15. FIG. 17B illustrates an enlarged cross-sectional configuration of a region corresponding to the region EX1 of FIG. 14.

Referring to FIG. 17B, to form the plurality of lower via holes VHL, a PEALE process similar to that described with reference to FIG. 17A may be used. However, in a process of forming the plurality of lower via holes VHL, unlike the process of forming the plurality of upper via holes VHU described with reference to FIG. 17A, Ar⁺ positively charged in operation (C) may travel with directionality toward the plurality of lower metal wiring layer 130, which are each located relatively close to the lower surface of each of the plurality of upper via holes VHU and each include a relatively large amount of free electrons 130E, as indicated by the arrow A11. As a result, in an etching process for forming the plurality of lower via holes VHL, self-aligned etching may be performed in which etching is performed from each of the plurality of upper via holes VHU toward the lower metal wiring layer 130 that is adjacent to each upper via hole VHU.

Referring to FIG. 16, in the resulting product of FIG. 15, a metal-containing conductive layer may be formed to fill the plurality of lower via holes VHL, the plurality of upper via holes VHU, and the upper wiring trench LH. The metal-containing conductive layer may include a metal plug and a conductive barrier film that at least partially surrounds the sidewall and the lower surface of the metal plug. The metal plug may include, for example, Cu, W, Mo, Ru, Co, Al, or a combination thereof. For example, the metal plug may include Cu. The conductive barrier film may include a TiN film, a Tan film, a Co film, or a combination thereof. For example, when the metal plug includes Cu, the conductive barrier film may have a multilayered structure including a TaN film and a Co film, but the present inventive concept is not limited thereto. The plurality of conductive contact plugs VC1 and VC2 (see FIG. 1) and the upper metal wiring layer 150 may be formed from the metal-containing conductive layer.

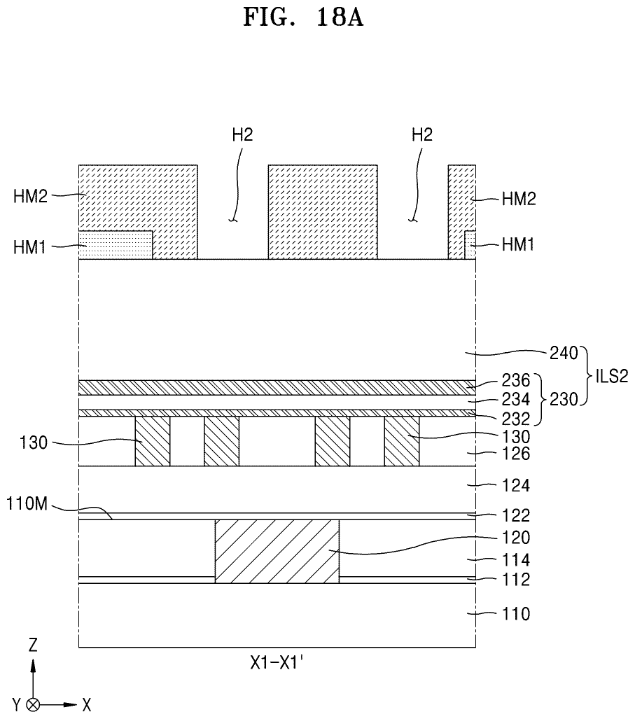

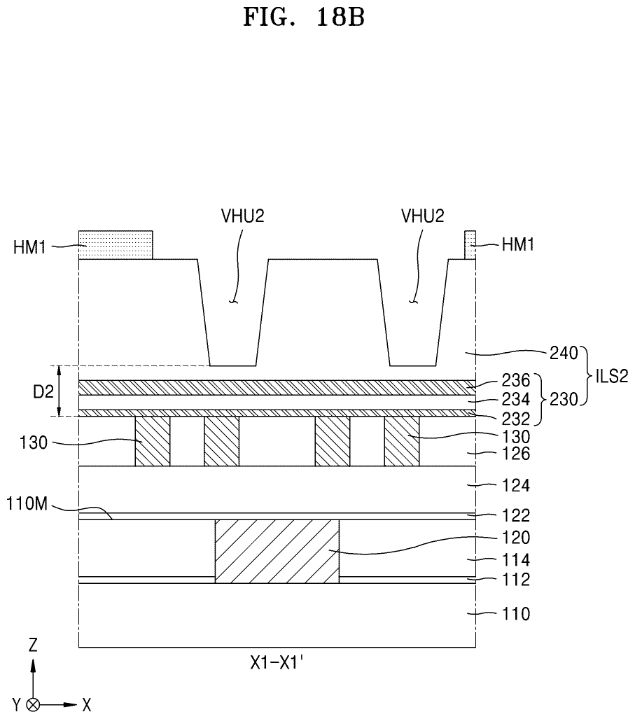

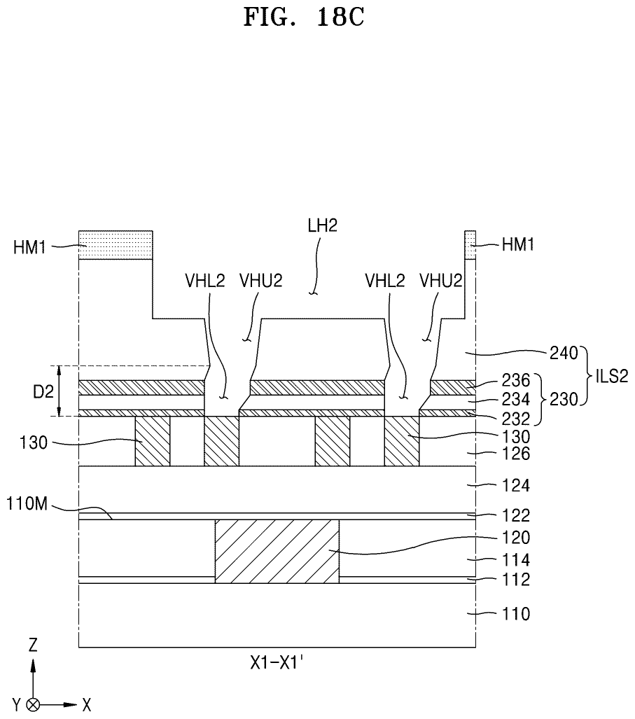

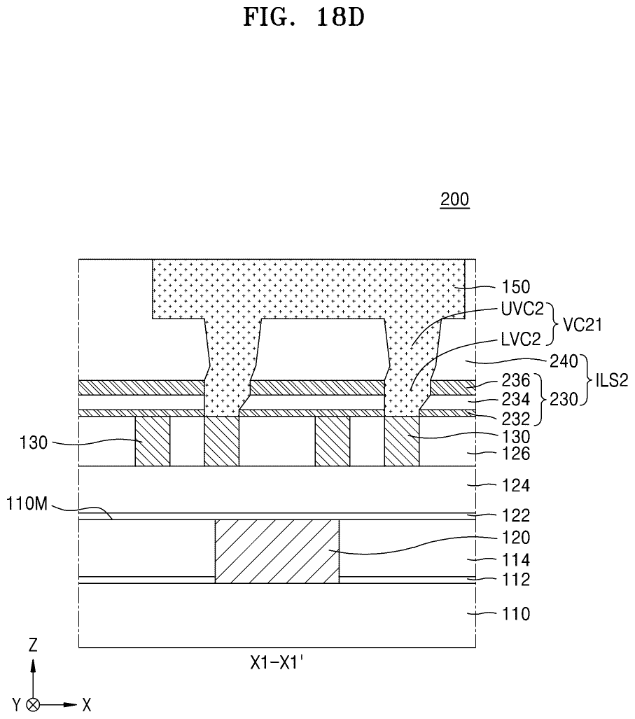

FIGS. 18A to 18D are cross-sectional views respectively illustrating a sequence of processes of an example of a method of fabricating an integrated circuit device, according to embodiments of the present inventive concept. An example of a method of fabricating the integrated circuit device 200A shown in FIG. 3 is described with reference to FIGS. 18A to 18D. In FIGS. 18A and 18D, the same reference numerals as in FIGS. 1 to 3 respectively denote the same members, and here, repeated descriptions thereof are omitted or briefly discussed.

Referring to FIG. 18A, similar processes to the processes described with reference to FIGS. 11 to 13B may be performed. However, in the present example, in the process described with reference to FIG. 12A, instead of forming the upper insulating structure ILS including the upper insulating film 140, the upper insulating structure ILS2 including the etch stop film 230 and the upper insulating film 240 may be formed.

Referring to FIG. 18B, similar to the description made with reference to FIG. 14, the upper insulating film 140 may be etched by as much as a certain thickness by using the first hardmask pattern HM1 and the second hardmask pattern HM2 as an etch mask, thereby forming a plurality of upper via holes VHU2 in the upper insulating film 140. Next, the second hardmask pattern HM2 may be removed.

After the plurality of upper via holes VHU2 are formed, the lower surface of each of the plurality of upper via holes VHU2 may be separated from the upper surface of each of the plurality of lower metal wiring layers 130 by as much as a vertical distance D2. In embodiments of the present inventive concept, the thickness, which corresponds to the vertical distance D2, of the upper insulating film 140 exposed at the lower surface of each of the plurality of upper via holes VHU2 may be, but is not limited to, about 5 nm to about 20 nm, for example, about 8 nm to about 12 nm.

Referring to FIG. 18C, similar to the description made with reference to FIG. 15, in the resulting product of FIG. 18B, the upper insulating film 140 and the etch stop film 230 may be etched by using the first hardmask pattern HM1 as an etch mask, thereby forming an upper wiring trench LH2 and a plurality of lower via holes VHL2. The upper wiring trench LH2 may be connected with the plurality of lower via holes VHL2 through the plurality of upper via holes VHU2.

When the plurality of lower via holes VHL2 are formed, a process of etching the upper insulating film 140 exposed by the plurality of upper via holes VHU2 and a process of etching the second insulating film 234 of the etch stop film 230 may each be performed by a PEALE process as described with reference to FIG. 17B. For example, in each of the process of etching the upper insulating film 140 exposed by the plurality of upper via holes VHU2 and the process of etching the second insulating film 234 of the etch stop film 230, positively charged Ar⁺ may travel with directionality toward the plurality of lower metal wiring layer 130, which are each located relatively close to the lower surface of each of the plurality of upper via holes VHU2 and each include a relatively large amount of free electrons 130E. As a result, in each of the process of etching the upper insulating film 140 exposed by the plurality of upper via holes VHU2 and the process of etching the second insulating film 234 of the etch stop film 230, self-aligned etching may be performed in which etching is performed from each of the plurality of upper via holes VHU2 toward the lower metal wiring layer 130 that is adjacent to each upper via hole VHU2.

When the plurality of lower via holes VHL2 are formed, a process of etching each of the first insulating film 232 and the third insulating film 236 of the etch stop film 230 may be performed by a wet-etching process. As a result, after the plurality of lower via holes VHL2 are formed, the respectively sidewalls of the first insulating film 232, the second insulating film 234, and the third insulating film 236 of the etch stop film 230, which are exposed by each of the plurality of lower via holes VHL2, may have unequal inclinations from each other.

Referring to FIG. 18D, in the resulting product of FIG. 18C, a metal-containing conductive layer may be formed to fill the plurality of lower via holes VHL2, the plurality of upper via holes VHU2, and the upper wiring trench LH2 by a similar method to that described with reference to FIG. 16. The plurality of conductive contact plugs VC21 and the upper metal wiring layer 150 may be formed from the metal-containing conductive layer.

Heretofore, while the examples of the methods of respectively fabricating the integrated circuit devices 100 and 200A shown in FIGS. 1 to 3 have been described with reference to FIGS. 11 to 18D, it will be understood by those of ordinary skill in the art that, by making various modifications and changes to the examples described with reference to FIGS. 11 to 18D, the integrated circuit devices 200B, 300, 400, and 500 shown in FIGS. 4 to 10 and integrated circuit devices having various structures modified and changed therefrom without departing from the spirit and scope of the present inventive concept may be fabricated.

While the present inventive concept has been described with reference to embodiments thereof, it will be understood by those of ordinary skill in the art that various changes in form and details may be made thereto without departing from the spirit and scope of the present inventive concept.

What is claimed is:

1. An integrated circuit device comprising:
a lower insulating film arranged on a substrate;
a lower metal wiring layer passing through the lower insulating film;
an upper insulating film arranged on the lower insulating film and the lower metal wiring layer;
an upper metal wiring layer arranged on the upper insulating film; and
a conductive contact plug passing through the upper insulating film in a vertical direction and disposed between the lower metal wiring layer and the upper metal wiring layer,
wherein a first center of an uppermost portion farthest from the substrate, of the conductive contact plug, is shifted in a horizontal direction, which is parallel to a main surface of the substrate, from a second center of a lowermost portion closest to the substrate, of the conductive contact plug.

2. The integrated circuit device of claim 1, wherein a central-axis extension direction of the conductive contact plug varies as the substrate is approached from the upper metal wiring layer.

3. The integrated circuit device of claim 1, wherein the upper metal wiring layer extends lengthwise in a first horizontal direction that is parallel to the main surface of the substrate,
the lower metal wiring layer extends lengthwise in a second horizontal direction that is parallel to the main surface of the substrate and intersects with the first horizontal direction, and
the first center of the uppermost portion of the conductive contact plug, which is farthest from the substrate, is shifted from a reference center of an intersection region, which is formed between the lower metal wiring layer and the upper metal wiring layer, by a distance greater than 0 in the first horizontal direction.

4. The integrated circuit device of claim 1, wherein the upper metal wiring layer extends lengthwise in a first horizontal direction that is parallel to the main surface of the substrate,
the lower metal wiring layer extends lengthwise in a second horizontal direction that is parallel to the main surface of the substrate and intersects with the first horizontal direction, and
the first center of the uppermost portion of the conductive contact plug, which is farthest from the substrate, is shifted from a reference center of an intersection region, which is formed between the lower metal wiring layer and the upper metal wiring layer, by a distance greater than 0 in the second horizontal direction.

5. The integrated circuit device of claim 1, wherein a first central axis of an upper contact portion of the conductive contact plug, which is adjacent to the upper metal wiring layer, extends in the vertical direction, and
a second central axis of a lower contact portion of the conductive contact plug, which is adjacent to the lower metal wiring layer, extends in a direction that is slanted with respect to the first central axis of the upper contact portion of the conductive contact plug.

6. The integrated circuit device of claim 1, wherein the conductive contact plug and the upper metal wiring layer are integrally connected with each other.

7. The integrated circuit device of claim 1, further comprising an etch stop film including a metal and arranged between the lower insulating film and the upper insulating film,
wherein a portion of the conductive contact plug passes through the etch stop film,
a first inclination of a first surface of the conductive contact plug, which faces the upper insulating film, is different from a second inclination of a second surface of the conductive contact plug, which faces the etch stop film, and
the first inclination of the first surface of the conductive contact plug meets the second inclination of the second surface of the conductive contact plug at a boundary between the etch stop film and the upper insulating film.

8. The integrated circuit device of claim 7, wherein an inclined direction of the second surface of the conductive contact plug is closer to a third direction, which is substantially perpendicular to the main surface of the substrate and crosses the horizontal direction, than an inclined direction of the first surface of the conductive contact plug.

9. The integrated circuit device of claim 1, further comprising an etch stop film arranged between the lower insulating film and the upper insulating film and having a multilayered structure that comprises a first insulating film, which includes a metal, and a second insulating film, which does not include a metal,
wherein a portion of the conductive contact plug passes through the etch stop film, and
a first inclination of a surface of the conductive contact plug, which faces the upper insulating film, a second inclination of a surface of the conductive contact plug, which faces the first insulating film of the etch stop film, and a third inclination of a surface of the conductive contact plug, which faces the second insulating film of the etch stop film, are different are different from one another.

10. An integrated circuit device comprising:
a lower insulating film arranged on a substrate;
a plurality of lower metal wiring layers spaced apart from each other in a first direction and extending lengthwise in a second direction that intersects with the first direction, wherein each of the plurality of lower metal wiring layers are disposed in the lower insulating film;
an upper insulating film arranged on the lower insulating film and the plurality of lower metal wiring layers;
a first upper metal wiring layer arranged on the upper insulating film to overlap a first lower metal wiring layer of the plurality of lower metal wiring layers and a second lower metal wiring layer of the plurality of lower metal wiring layers, and extending lengthwise in the first direction;
a first conductive contact plug disposed in the upper insulating film and contacting each of the first lower metal wiring layer and the first upper metal wiring layer; and
a second conductive contact plug disposed in the upper insulating film and contacting each of the second lower metal wiring layer and the first upper metal wiring layer,
wherein, in each of the first conductive contact plug and the second conductive contact plug, a first center of an uppermost portion farthest from the substrate is shifted in a horizontal direction, which is parallel to a main surface of the substrate, from a second center of a lowermost portion closest to the substrate.

11. The integrated circuit device of claim 10, wherein, the first center of the uppermost portion of the first conductive contact plug, which is farthest from the substrate, is shifted from a first reference center of an intersection region, which is formed between the first lower metal wiring layer and the first upper metal wiring layer, by a first distance greater than 0 in the first direction, and
the first center of the uppermost portion of the second conductive contact plug, which is farthest from the substrate, is shifted from a second reference center of an intersection region, which is formed between the second lower metal wiring layer and the first upper metal wiring layer, by the first distance in the first direction.

12. The integrated circuit device of claim 10, wherein, the first center of the uppermost portion of the first conductive contact plug, which is farthest from the substrate, is shifted from a first reference center of an intersection region, which is formed between the first lower metal wiring layer and the first upper metal wiring layer, by a second distance greater than 0 in the second direction, and
the first center of the uppermost portion of the second conductive contact plug, which is farthest from the substrate, is shifted from a second reference center of an intersection region, which is formed between the second lower metal wiring layer and the first upper metal wiring layer, by the second distance in the second direction.

13. The integrated circuit device of claim 10, wherein, in each of the first conductive contact plug and the second conductive contact plug,
a first central axis of an upper contact portion adjacent to the first upper metal wiring layer extends in a vertical direction, and
a second central axis of a lower contact portion, which is closer to the substrate than the upper contact portion, extends in a direction that is slanted with respect to the first central axis of the upper contact portion.

14. The integrated circuit device of claim 10, further comprising:
a second upper metal wiring layer arranged on the upper insulating film to overlap a third lower metal wiring layer of the plurality of lower metal wiring layers, and extending lengthwise in the first direction; and
a third conductive contact plug disposed in the upper insulating film and contacting each of the third lower metal wiring layer and the second upper metal wiring layer,
wherein the first center of the uppermost portion of the first conductive contact plug, which is farthest from the substrate, is shifted from a first reference center of an intersection region, which is formed between the first lower metal wiring layer and the first upper metal wiring layer, by a first distance greater than 0 in the first direction, and
a center of an uppermost portion of the third conductive contact plug, which is farthest from the substrate, is shifted from a third reference center of an intersection region, which is formed between the third lower metal wiring layer and the second upper metal wiring layer, by a second distance greater than 0 in a direction opposite to the first direction.

15. The integrated circuit device of claim 10, further comprising:
a second upper metal wiring layer arranged on the upper insulating film to overlap a third lower metal wiring layer of the plurality of lower metal wiring layers, and extending lengthwise in the first direction; and
a third conductive contact plug disposed in the upper insulating film and contacting each of the third lower metal wiring layer and the second upper metal wiring layer,
wherein the first center of the uppermost portion of the first conductive contact plug, which is farthest from the substrate, is shifted from a first reference center of an intersection region, which is formed between the first lower metal wiring layer and the first upper metal wiring layer, by a first distance greater than 0 in the second direction, and
a center of an uppermost portion of the third conductive contact plug, which is farthest from the substrate, is shifted from a third reference center of an intersection region, which is formed between the third lower metal wiring layer and the second upper metal wiring layer, by a second distance greater than 0 in a direction opposite to the second direction.

16. The integrated circuit device of claim 10, further comprising an etch stop film arranged between the lower insulating film and the upper insulating film and having a multilayered structure that comprises a first insulating film, which includes a metal, and a second insulating film, which does not include a metal,
wherein a portion of each of the first conductive contact plug and the second conductive contact plug passes through the etch stop film, and
in each of the first conductive contact plug and the second conductive contact plug, a first inclination of a surface facing the upper insulating film, a second inclination of a surface facing the first insulating film of the etch stop film, and a third inclination of a surface facing the second insulating film of the etch stop film are different from one another.

17. An integrated circuit device comprising:
a lower structure arranged on a substrate;
a lower insulating film arranged on the lower structure;
a plurality of lower metal wiring layers spaced apart from each other in a first direction and extending lengthwise in a second direction that intersects with the first direction, wherein each of the plurality of lower metal wiring layers pass through the lower insulating film;
an etch stop film arranged on the lower insulating film and the plurality of lower metal wiring layers and having a multilayered structure that comprises at least one aluminum (Al)-containing film;
an upper insulating film covering an upper surface of the etch stop film;
a first upper metal wiring layer arranged on the upper insulating film to overlap a first lower metal wiring layer of the plurality of lower metal wiring layers and a second lower metal wiring layer of the plurality of lower metal wiring layers, and extending lengthwise in the first direction;
a first conductive contact plug passing through the upper insulating film and the etch stop film and disposed between the first lower metal wiring layer and the first upper metal wiring layer; and
a second conductive contact plug passing through the upper insulating film and the etch stop film and disposed between the second lower metal wiring layer and the first upper metal wiring layer,
wherein, in each of the first conductive contact plug and the second conductive contact plug, a first center of an uppermost portion farthest from the substrate is shifted in the first direction or the second direction from a second center of a lowermost portion closest to the substrate, and
a central-axis extension direction of each of the first conductive contact plug and the second conductive contact plug varies as the substrate is approached from the upper metal wiring layer.

18. The integrated circuit device of claim 17, wherein the first center of the uppermost portion of the first conductive contact plug, which is farthest from the substrate, is shifted from a first reference center of an intersection region, which is formed between the first lower metal wiring layer and the first upper metal wiring layer, by a first distance greater than 0 in the first direction, and
the first center of the uppermost portion of the second conductive contact plug, which is farthest from the substrate, is shifted from a second reference center of an intersection region, which is formed between the second lower metal wiring layer and the first upper metal wiring layer, by the first distance in the first direction.

19. The integrated circuit device of claim 17, wherein the first center of the uppermost portion of the first conductive contact plug, which is farthest from the substrate, is shifted from a first reference center of an intersection region, which is formed between the first lower metal wiring layer and the first upper metal wiring layer, by a second distance greater than 0 in the second direction, and
the first center of the uppermost portion of the second conductive contact plug, which is farthest from the substrate, is shifted from a second reference center of an intersection region, which is formed between the second lower metal wiring layer and the first upper metal wiring layer, by the second distance in the second direction.

20. The integrated circuit device of claim 17, further comprising:
a second upper metal wiring layer arranged on the upper insulating film to overlap a third lower metal wiring layer of the plurality of lower metal wiring layers, and extending lengthwise in the first direction; and
a third conductive contact plug passing through the upper insulating film and contacting each of the third lower metal wiring layer and the second upper metal wiring layer,
wherein the first center of the uppermost portion of the first conductive contact plug, which is farthest from the substrate, is shifted from a first reference center of an intersection region, which is formed between the first lower metal wiring layer and the first upper metal wiring layer, by a first distance greater than 0 in the first direction or the second direction, and
a center of an uppermost portion of the third conductive contact plug, which is farthest from the substrate, is shifted from a third reference center of an intersection region, which is formed between the third lower metal wiring layer and the second upper metal wiring layer, by a second distance greater than 0 in a direction opposite to the first direction or a direction opposite to the second direction.
